(19) United States
(12) Patent Application Publication
(10) Pub. No.: US 2026/0129879 A1
(43) Pub. Date: May 7, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Min-Ying TSAI, Kaohsiung City (TW); Cheng-Hsien CHOU, Tainan City (TW); I Wen HUANG, Tainan City (TW)

(21) Appl. No.: 18/939,897

(22) Filed: Nov. 7, 2024

(51) Int. Cl. H01L 27/146

(52) U.S. Cl. CPC H10D 1/042; H10D 1/716; H10F 39/014

(57) ABSTRACT

An image sensor device includes a capacitor structure that includes, as a dielectric material, an amorphous composition that includes a mixture of metal oxides. The amorphous composition replaces crystalline metal oxide dielectric layer stacks used in other approaches. The amorphous composition reduces or prevents interface defects and electron traps as compared to the crystalline metal oxide dielectric layer stacks. A single amorphous layer avoids the interfaces between metal oxides and metal oxide crystal defects in which the electron traps can be easily formed. The resulting image sensor device exhibits reduced lag as compared to other approaches that use crystalline metal oxide dielectric layer stacks. In addition, using the single amorphous layer including the mixture of metal oxides increases capacitance of a corresponding capacitor structure as compared to other approaches that use the crystalline metal oxide dielectric layer stacks.

### BACKGROUND

A complementary metal oxide semiconductor (CMOS) image sensor may include a plurality of pixel sensors arranged in a pixel sensor array. A pixel sensor of the CMOS image sensor may include a photodiode configured to convert photons of incident light to a photocurrent of electrons. The magnitude of the photocurrent is based at least in part on the intensity of the incident light. Accordingly, if the pixel sensors in the pixel sensor array are capable of sensing incident light across a broad range of intensity, a high range of brightness and contrast may be achieved in images and/or video generated by the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of example circuits for a pixel sensor described herein.

FIGS. 2A and 2B are diagrams of an example semiconductor device described herein.

FIGS. 3A-3E are diagrams of an example implementation of forming a semiconductor device described herein.

FIGS. 4A-4Q are diagrams of an example implementation of forming a trench capacitor structure described herein.

FIGS. 5A and 5B are diagrams of an example implementation of an insulator layer of a capacitor structure described herein.

FIG. 6 illustrates an elemental composition of an insulator layer of a capacitor structure described herein.

FIG. 7 is a diagram of an example semiconductor device described herein.

FIG. 8 is a diagram of an example semiconductor device described herein.

FIG. 9 is a diagram of an example semiconductor device described herein.

FIG. 10 is a flowchart of an example process associated with forming a semiconductor device described herein.

FIG. 11 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a pixel sensor may be limited in the number of photons of incident light that can be absorbed before reaching saturation of the pixel sensor. “Saturation” refers to a level of photon absorption past which additional photons of light cannot be absorbed by the pixel sensor. Saturation of the pixel sensor results in limited dynamic range for the pixel sensor because additional brightness and color information cannot be obtained from further absorption of photons.

The amount of photocurrent charge that can be stored in a pixel sensor before reaching saturation may be referred to as the full well capacity (FWC) of the pixel sensor. The full well capacity of the pixel sensor may be based at least in part on the size (e.g., the depth, the width, the volume) of the photodiode of the pixel sensor and/or the shape of the photodiode, among other examples. While increasing the size of the photodiode may increase the full well capacity of the pixel sensor, doing so may come at the expense of decreasing the density of pixel sensors in the pixel sensor array, which may reduce the resolution of the pixel sensor array.

To increase the FWC of a pixel sensor, an image sensor device (e.g., a complementary metal-oxide-semiconductor (CMOS) image sensor device) may include a capacitor structure that is configured to store charge associated with a photocurrent that is generated by the pixel sensor prior to the charge being transferred to a floating diffusion node associated with the pixel sensor. The photocurrent may be transferred from the pixel sensor to the capacitor structure, which enables the pixel sensor to generate more charge for the photocurrent than if the photocurrent were wholly stored in the photodiode and/or in the floating diffusion node. Thus, the capacitor structure may increase the FWC of the pixel sensor, which may enable a higher range of brightness and/or contrast to be achieved in images and/or video generated by the pixel sensor array. The capacitor structure is designed to achieve a small lateral footprint for the capacitor structure, and may include a metal-insulator-metal (MIM) layer stack in which bottom electrode layers and top electrode layers are arranged in an alternating manner and separated by insulator layers.

However, some high-density MIM capacitors may suffer from degraded imaging performance when the insulating layers of the MIM capacitors include stacks of crystalline material. For example, a crystalline insulator layer stack of zirconium oxide (ZrOₓ such as ZrO₂) and aluminum oxide (AlₓO_{y} such as Al₂O₃), such as a ZrO₂/Al₂O₃/ZrO₂ (ZAZ) dielectric layer stack, may be susceptible to charge trapping, which can lead to delays in discharging an MIM capacitor that includes the crystalline insulator layer stack. With a ZrO₂/Al₂O₃/ZrO₂ (ZAZ) arrangement, the interfaces between zirconium oxide layers and the aluminum oxide layer, along with crystal defects in zirconium oxide layers, may result in current leakage paths and electron traps. In more detail, oxygen may migrate from the crystallized zirconium oxide in the zirconium oxide layers, particularly at the interfaces between zirconium oxide layers and the aluminum oxide layer, leading to crystal defects referred to as oxygen vacancies. These oxygen vacancies may act as electron traps that trap electrons in the MIM capacitor (e.g., from the electrode layers of the MIM capacitor), which increases the discharge time for the MIM capacitor and leads to lag in generating images and/or video.

In some implementations described herein, an image sensor device (e.g., a CMOS image sensor device) includes a capacitor structure (e.g., an MIM capacitor) that includes an insulator layer having an amorphous composition that includes a mixture of zirconium, aluminum, and oxygen. The amorphous composition reduces or prevents interface defects and electron traps, in comparison to crystalline insulator layer stacks such as a ZrO₂/Al₂O₃/ZrO₂ (ZAZ) dielectric layer stack. In particular, the amorphous composition of the insulator layer avoids interfaces between distinct zirconium oxide layers and an aluminum oxide layer, which reduces and/or prevents crystal defects such as oxygen vacancies from forming in the insulator layer. The resulting image sensor device exhibits reduced lag in generating images and/or video because charge trapping is reduced, minimized, and/or prevented in the capacitor structure due to the reduced and/or prevented crystal defects. For example, in some implementations, the image sensor device may exhibit a reduction in lag in generating images and/or video by greater than 20% in comparison to other capacitor structures that include a ZrO₂/Al₂O₃/ZrO₂ (ZAZ) dielectric layer stack. In addition, the amorphous composition of the insulator layer may increase capacitance of the capacitor structure in comparison to other capacitor structures that include a ZrO₂/Al₂O₃/ZrO₂ (ZAZ) dielectric layer stack. For example, in some implementations, capacitance of the capacitor structure can be increased by approximately 30% in comparison to the other approaches.

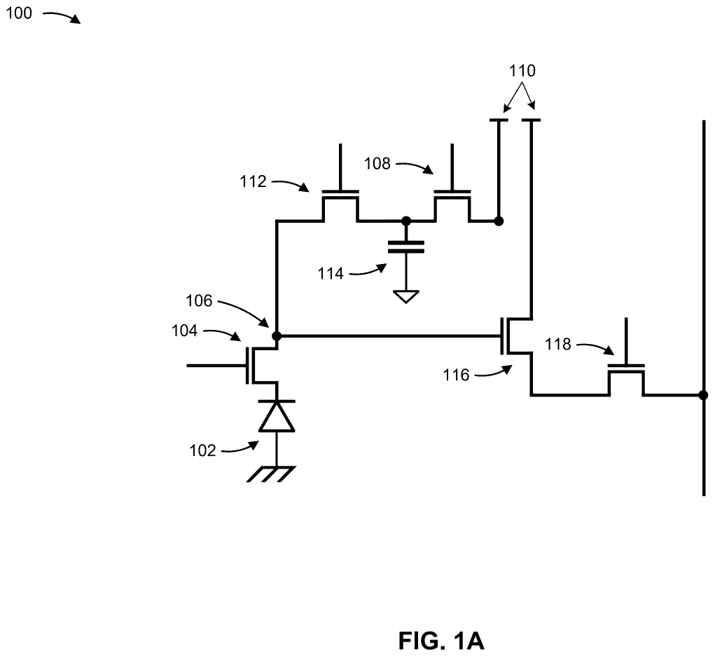

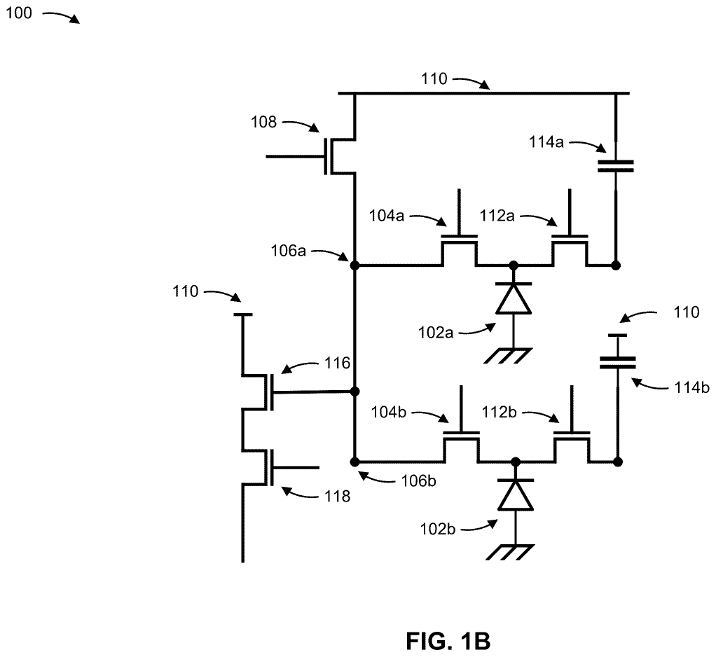

FIGS. 1A and 1B are diagrams of example circuits for a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor.

As shown in an example circuit in FIG. 1A, a pixel sensor 100 includes a photodiode 102 that may be configured to sense and/or accumulate incident light (e.g., light directed toward the pixel sensor 100) and convert photons of the incident light to a photocurrent. The magnitude of the photocurrent may be based on the number of photons (e.g., the intensity of the incident light) collected in the photodiode 102. Thus, the accumulation of photons in the photodiode 102 generates a build-up of electrical charge that represents the intensity or brightness of the incident light (e.g., a greater amount of charge may correspond to a greater intensity or brightness, and a lesser amount of charge may correspond to a lower intensity or brightness).

The photodiode 102 is electrically connected with a transfer gate 104. The transfer gate 104 is configured to control the transfer of the photocurrent from the photodiode to a floating diffusion node 106. The transfer gate 104 may be selectively switched by applying a transfer voltage (Vₜₓ) to the transfer gate 104. In some implementations, the transfer voltage being applied to the transfer gate 104 causes a leakage path (e.g., a buried channel) to form between the photodiode 102 and the floating diffusion node 106 across the transfer gate 104, which enables the photocurrent to travel along the leakage path to the floating diffusion node 106. In some implementations, the transfer voltage being removed from the transfer gate 104 (or the absence of the transfer voltage) causes the leakage path to be removed, such that the photocurrent cannot pass from the photodiode 102 to the floating diffusion node 106.

The circuit for the pixel sensor 100 may further include a reset gate 108. The reset gate 108 is electrically connected to a voltage source 110. The reset gate 108 may be controlled to selectively apply a reset voltage (Vᵣₛₜ) to the floating diffusion node 106 from the voltage source 110. The transfer gate 104 and the reset gate 108 may be electrically coupled with the floating diffusion node 106 such that the reset voltage is applied to the floating diffusion node 106 to “reset” the floating diffusion node 106 (e.g., by draining any residual charge in the floating diffusion node 106) prior to activation of the transfer gate 104 to transfer a photocurrent from the photodiode 102 to the floating diffusion node 106.

The pixel sensor 100 may be a lateral overflow integration capacitor (LOFIC) pixel sensor that includes an overflow gate 112 and an overflow capacitor 114. The overflow capacitor 114 may be electrically coupled to the floating diffusion node 106 through the overflow gate 112 such that photocurrent may be transferred from the floating diffusion node 106 to the overflow capacitor 114 for temporary storage. The overflow gate 112 may selectively control the flow of photocurrent to and/or from the overflow capacitor 114. This enables additional photocurrent to be transferred to the floating diffusion node 106 from the photodiode 102 without causing the pixel sensor 100 to reach saturation, which increases the full well capacity and the dynamic range of the pixel sensor 100.

The photocurrent may be used to apply a floating diffusion voltage (Vid) to a source follower gate 116 of the circuit of the pixel sensor 100. This permits the photocurrent to be observed without removing or discharging the photocurrent from the floating diffusion node 106 and/or from the overflow capacitor 114. The reset gate 108 may instead be used to remove or discharge the photocurrent from the floating diffusion node 106 and/or from the overflow capacitor 114.

To apply the floating diffusion voltage to the source follower gate 116, the transfer gate 104 may be switched off (e.g., so that the photocurrent does not flow back into the photodiode 102) and the overflow gate 112 may be switched on. This configuration enables the photocurrent stored in floating diffusion node 106 and in the overflow capacitor 114 to be used to apply the floating diffusion voltage to the source follower gate 116.

The source follower gate 116 functions as a high impedance amplifier for the pixel sensor 100. The source follower gate 116 provides a voltage-to-current conversion of the floating diffusion voltage. The output of the source follower gate 116 is electrically connected with a row select gate 118, which is configured to control the flow of the photocurrent to external circuitry. The row select gate 118 is controlled by selectively applying a select voltage (V_{di}) to the gate of the row select gate 118. This permits the photocurrent to flow to an output of the pixel sensor 100.

As shown in another example circuit in FIG. 1B, a pixel sensor 100 may include a plurality of subcircuits. The subcircuits may include a small pixel subcircuit and a large pixel subcircuit. The small pixel subcircuit may include a small photodiode 102a, a transfer gate 104a, a floating diffusion node 106a, an overflow gate 112a, and an overflow capacitor 114a. The large pixel sensor subcircuit may include a large photodiode 102b, a transfer gate 104b, a floating diffusion node 106b, an overflow gate 112b, and an overflow capacitor 114b. The small pixel subcircuit and the large pixel subcircuit may both be connected to the reset gate 108, the voltage source 110, the source follower gate 116, and the row select gate 118. The large photodiode 102b may be physically larger than the small photodiode 102a, thereby enabling pixel sensor 100 to have different regions of photonic sensitivity.

As indicated above, FIGS. 1A and 1B are provided as examples. Other examples may differ from what is described with regard to FIGS. 1A and 1B.

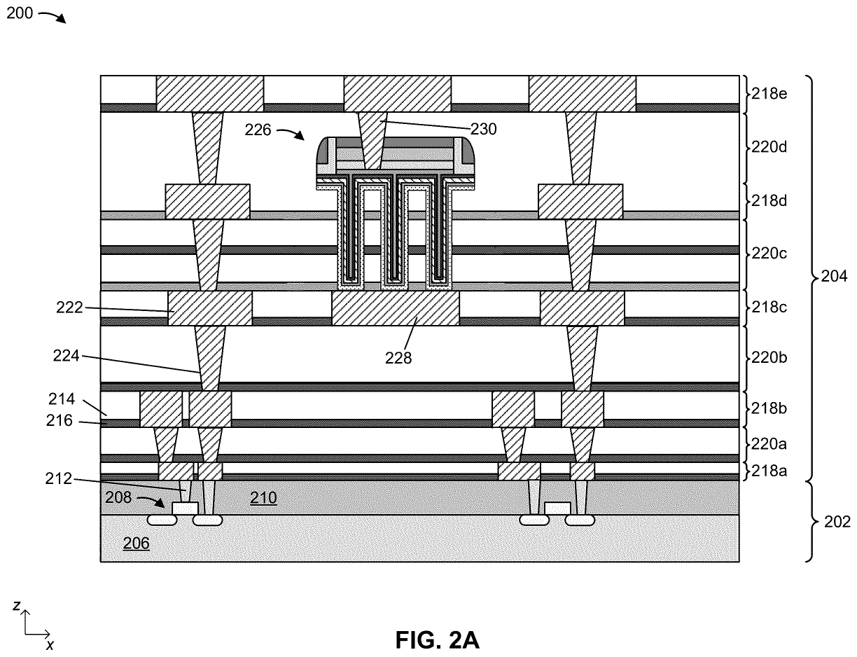

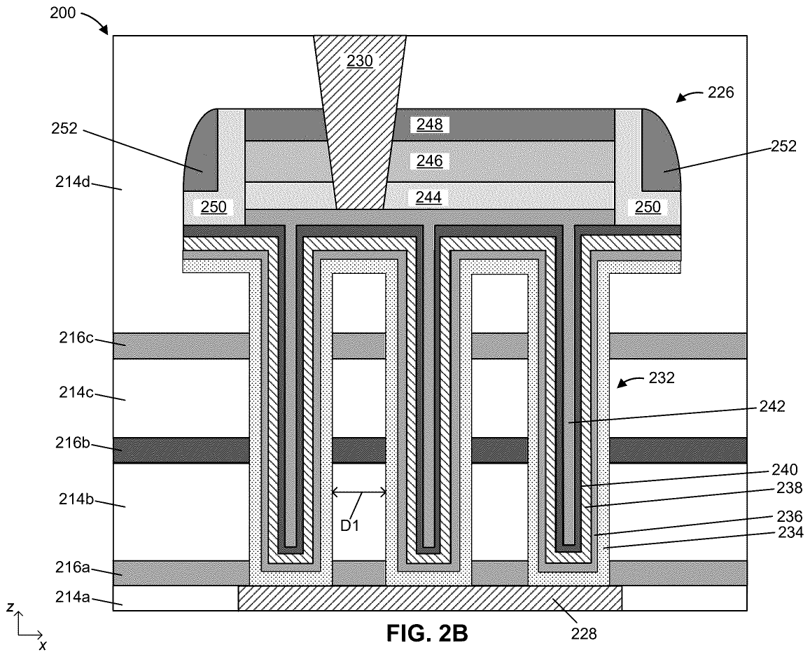

FIGS. 2A and 2B are diagrams of an example semiconductor device 200 described herein. The semiconductor device 200 may include system-on-chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device. In the case of an image sensor device, semiconductor device 200 may include an example structural implementation of an overflow capacitor 114 of a pixel sensor 100 described herein.

FIG. 2A illustrates a cross-section view of the semiconductor device 200. As shown in FIG. 2A, the semiconductor device 200 may include a device layer 202 and an interconnect layer 204 arranged in a z-direction in the semiconductor device 200 with respect to the device layer 202. For example, the interconnect layer 204 may be located above the device layer 202. As another example, the interconnect layer 204 may be located below the device layer 202.

The interconnect layer 204 may include conductive structures that are arranged to carry signals and/or provide power distribution throughout the semiconductor device 200. In some implementations, the semiconductor device 200 includes interconnect layers 204 above and below the device layer 202. A first interconnect layer 204 on a first side of the device layer 202 may be used for signal propagation throughout the semiconductor device 200, and a second interconnect layer 204 on an opposing second side of the device layer 202 may be used for power distribution in the semiconductor device 200.

The device layer 202 includes a substrate 206 of the semiconductor device 200. The substrate 206 may correspond to a portion of a semiconductor wafer on which the semiconductor device 200 is formed. The substrate 206 may include a silicon (Si) substrate, a substrate formed of a material including silicon, a III-V compound semiconductor material substrate such as gallium arsenide (GaAs), a silicon-on-insulator (SOI) substrate, or another type of substrate. The substrate 206 may extend in an x-direction and/or in a y-direction in the semiconductor device 200 such that the top and bottom surfaces of the substrate 206 are approximately orthogonal to the z-direction in the semiconductor device 200.

Integrated circuit devices 208 may be included in and/or on the substrate 206 in the device layer 202 of the semiconductor device 200. The integrated circuit devices 208 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receivers, optical circuits, and/or other types of front end semiconductor devices.

A front end transistor structure may include a plurality of source/drain regions, which may correspond to doped regions of the substrate 206, separated by a channel region in the substrate 206. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 210 is included over the substrate 206. The dielectric layer 210 includes an interlayer dielectric (ILD) layer, an etch stop layer (ESL), and/or another type of dielectric layer. The dielectric layer 210 includes dielectric material(s) that enable various portions of the substrate 206 and/or the integrated circuit devices 208 to be selectively etched or protected from etching, and/or to electrically isolate the integrated circuit devices 208 in the device layer 202. The dielectric layer 210 includes a silicon nitride (SiₓN_{y}), an oxide (e.g., a silicon oxide (SiOₓ) and/or another oxide material), and/or another type of dielectric material. The dielectric layer 210 may extend in the x-direction and/or in the y-direction in the semiconductor device 200. Contacts 212 (e.g., source/drain contacts, gate contacts) may extend through the dielectric layer 210 and between the integrated circuit devices 208 and the interconnect layer 204. The contacts may electrically connect the integrated circuit devices 208 to the interconnect layer 204. The contacts 212 may include vias, plugs, and/or another type of elongated electrically conductive structures. The contacts 212 may include tungsten (W), cobalt (Co), ruthenium (Ru), titanium (Ti), aluminum (Al), and/or gold (Au), among other electrically conductive materials.

The interconnect layer 204 includes a plurality of dielectric layers (e.g., back end dielectric layers) that are arranged in a direction (e.g., the z-direction) that is approximately perpendicular to the top surface of the substrate 206. The dielectric layers may include ILD layers 214 and ESLs 216 that are arranged in an alternating manner in the z-direction. The ILD layers 214 and the ESLs 216 may extend in the x-direction and/or in the y-direction in the semiconductor device 200.

The ILD layers 214 may each include a low dielectric constant (low-k) oxide material such as silicon oxide (SiOₓ) or undoped silicate glass (USG). Additionally and/or alternatively, the ILD layers 214 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 214 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 216 may each include a silicon nitride (SiₓN_{y}), silicon carbide (SiC), silicon oxynitride (SiON), and/or another suitable dielectric material. In some implementations, an ILD layer 214 and an ESL 216 include different dielectric materials to provide etch selectivity to enable various structures to be formed in the interconnect layer 204. For example, the ILD layers 214 may each include a low-k dielectric material such as USG, and the ESLs 216 may each include a high-k dielectric material such as silicon nitride (SiₓN_{y}) or silicon carbide (SIC). Additionally and/or alternatively, two or more ESLs 216 may include different materials. For example, one or more first ESLs 216 may include silicon nitride (SiₓN_{y}), and one or more second ESLs 216 may include silicon carbide (SIC).

The interconnect layer 204 includes a plurality of conductive structures that are arranged in a plurality of layers. The conductive structures may be electrically coupled and/or physically coupled with one or more of the integrated circuit devices 208 in the device layer 202. The conductive structures provide electrical routing that enables signals and/or power to be provided to and/or from the integrated circuit devices 208.

The layers of conductive structures may include a plurality of layers 218a-218e that are vertically arranged and alternate with a plurality of layers 220a-220d in the z-direction (e.g., vertically alternate). The layers 218a-218e each include a layer of metallization structures 222, and the layers 220a-220d each include a layer of interconnect structures 224.

The layers 218a-218e of metallization structures 222 may be referred to as M-layers. For example, a layer 218a of metallization structures 222 (referred to as a metal-0 (M0) layer) may be located at the bottom of the interconnect layer 204 and may be coupled with the device layer 202. In particular, the metallization structures 222 in the M0 layer may be coupled with the contacts 212 (e.g., a contact layer referred to as “CO”-layer) of the integrated circuit devices 208 in the device layer 202. A layer 218b of metallization structures 222 (referred to as a metal-1 layer (M1) layer) may be located above the layer 218a of metallization structures 222 in the interconnect layer 204, a layer 218c of metallization structures 222 (referred to as a metal-2 layer (M2) layer) may be located above a layer 218b of metallization structures 222, and so on.

A layer 220a of interconnect structures 224 (referred to as a via-1 (V0) layer) may be included between the M0 layer and the M1 layer to interconnect the M0 layer and the M1 layer, a layer 220b of interconnect structures 224 (referred to as a via-2 (V1) layer) may be included between the M1 layer and the M2 layer to interconnect the M1 layer and the M2 layer, and so on.

The metallization structures 222 may include a combination of trenches, metallization layers, conductive traces, and/or other types of conductive structures. The interconnect structures 224 may include a combination of vias, interconnects, and/or other types of conductive structures. The metallization structures 222 and the interconnect structures 224 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 204 and the metallization structures 222, and/or between the dielectric layers of the interconnect layer 204 the interconnect structures 224. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 222, a topmost layer of interconnect structures 224) may be coupled to connection structures at the top of the semiconductor device 200. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 222, a topmost layer of interconnect structures 224) may be coupled to bonding structures, such as bonding pads and/or bonding vias.

As further shown in FIG. 2A, a trench capacitor structure 226 is included in the interconnect layer 204 of the semiconductor device 200. The trench capacitor structure 226 is an example structural implementation of the overflow capacitor 114 of the pixel sensor 100.

In general, a capacitor structure may include an MIM structure in which an insulator layer is sandwiched between two conductive electrode layers. The capacitance of the capacitor structure (e.g., the amount of charge that can be stored by the capacitor structure) is directly dependent on the geometry of the conductive electrode layers of the capacitor structure. The greater the area of the conductive electrode layers, the greater the capacitance of the capacitor structure. Thus, increasing the size of the metal electrode layers may increase the capacitance of the capacitor structure.

Increasing a lateral size of the capacitor structure is in direct contention with semiconductor design principles in the semiconductor industry, in which reducing semiconductor device sizes is pursued to achieve reduced power consumption, to achieve greater operating performance and efficiencies, and/or to enable semiconductor devices to be used in increasingly smaller form factor applications. Thus, in some cases, the size of a capacitor structure may be increased in a vertical direction in a semiconductor device such that the capacitor structure extends through a plurality of layers in a semiconductor device. A deep trench capacitor (DTC) is a type of capacitor structure that is formed in a deep trench in a semiconductor device such that the electrode layers and insulator layer extend along, and conform to, a profile of the deep trench. This enables the area of the conductive electrode layers to be increased (which increases the capacitance) with minimal increase in the lateral size of the capacitor structure. The trench of a DTC structure is typically formed to have a high aspect ratio between the depth of the trench and the width of the trench.

Referring to FIG. 2A, the trench capacitor structure 226 may include a DTC structure that extends through and/or may be included in one or more dielectric layers in the interconnect layer 204, such as one or more ILD layers 214 and/or one or more ESLs 216. In some implementations, a trench capacitor structure 226 is configured to store a charge (e.g., a photocurrent) for an integrated circuit device 208 (e.g., a pixel sensor) in the semiconductor device 200. In some implementations, an integrated circuit device 208 is electrically coupled to a trench capacitor structure 226 to form a memory cell (e.g., a dynamic random access memory (DRAM) cell or another type of capacitor-based memory cell) in the semiconductor device 200. In some implementations, a trench capacitor structure 226 is configured to provide charge decoupling for one or more integrated circuit devices 208. In some implementations, a trench capacitor structure 226 is configured to perform another function in the semiconductor device 200.

The trench capacitor structure 226 may be electrically coupled and/or physically coupled to a bottom contact 228 at a bottom of the trench capacitor structure 226, and to a top contact 230 at a top of the trench capacitor structure 226. Alternatively, the trench capacitor structure 226 may be electrically coupled and/or physically coupled to a plurality of top contacts at the top of the trench capacitor structure 226. The bottom contact 228 and the top contact 230 may each include one or more conductive structures in the interconnect layer 204, such as one or more metallization structures 222 and/or one or more interconnect structures 224, among other examples.

FIG. 2B illustrates a detailed cross-section view of the trench capacitor structure 226. As shown in FIG. 2B, the trench capacitor structure 226 includes one or more trenches 232 on the bottom contact 228. The bottom contact 228 may be included in an ILD layer 214a in the interconnect layer 204 of the semiconductor device 200. A trench 232 of the trench capacitor structure 226 may extend through one or more dielectric layers in the interconnect layer 204 of the semiconductor device 200, including through an ESL 216a, an ILD layer 214a, an ESL 216b, an ILD layer 214c, an ESL 216c, and/or an ILD layer 214d, among other examples. In some implementations, the trench(es) 232 may have a high aspect ratio, which is a ratio of a depth (or height) of the trench(es) 232 to a lateral width (or critical dimension) of the trench(es) 232. Thus, the trench capacitor structure 226 may be referred to as a DTC structure. In some implementations, the aspect ratio of a trench 232 may be approximately 10:1 or greater. In some implementations, a trench 232 may have an aspect ratio that is included in the range of approximately 20:1 to approximately 50:1. However, other values and ranges are within the scope of the present disclosure.

As further shown in FIG. 2B, the trench capacitor structure 226 includes a plurality of conformal layers that conform to the profile of the trench(es) 232. The conformal layers may include an adhesion layer 234, a bottom electrode layer 236 on the adhesion layer 234, a buffer layer 238 on the bottom electrode layer 236, and an insulator layer 240 on the buffer layer 238. The adhesion layer 234, the bottom electrode layer 236, the buffer layer 238, and the insulator layer 240 may each conform to the profile of the trench(es) 232 such that the adhesion layer 234, the bottom electrode layer 236, the buffer layer 238, and the insulator layer 240 conform to the sidewalls and the bottom surfaces of the trench(es) 232. The trench capacitor structure 226 further includes a top electrode layer 242 on the insulator layer 240. In some implementations, the top electrode layer 242 is a fill layer that fills in the remaining areas of the trench(es) 232. Alternatively, the top electrode layer 242 may also be a conformal layer that conforms to the sidewalls and the bottom surfaces of the trench(es) 232, and a dielectric plug layer or fill layer is further included in the remaining areas of the trench(es) 232.

The adhesion layer 234 may also be referred to as a glue layer, and may be included to promote adhesion of the bottom electrode layer 236 to the dielectric layers (e.g., the ILD layers 214b, 214c, and 214d, the ESLs 216a, 216b, and 216c) and/or to the bottom contact 228. The adhesion layer 234 may also act as a barrier layer that prevents upward migration of an electrically conductive material (e.g., copper (Cu)) of the bottom contact 228 into the bottom electrode layer 236. The adhesion layer 234 may include tantalum (Ta), tantalum nitride (TaN), and/or another suitable adhesion material.

The bottom electrode layer 236, the insulator layer 240, and the top electrode layer 242 correspond to an MIM structure of the trench capacitor structure 226. Thus, the trench capacitor structure 226 may also be referred to as an MIM capacitor structure. The bottom electrode layer 236 (also referred to as a capacitor bottom metal (CBM)) and the top electrode layer 242 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the bottom electrode layer 236 and the top electrode layer 242 include the same material or the same material composition. In some implementations, the bottom electrode layer 236 and the top electrode layer 242 include different materials or different material compositions.

The buffer layer 238 may include one or more materials. For example, the buffer layer 238 may include a material that promotes or facilitates lattice matching between the bottom electrode layer 236 and the buffer layer 238, and/or may include a material that promotes or facilitates lattice matching between the insulator layer 240 and the buffer layer 238.

In implementations in which the bottom electrode layer 236 includes a nitrogen-containing material or a nitride-containing material such as a titanium nitride (TiₓN such as Ti₂N), the material of the buffer layer 238 may also include a nitrogen-containing material or a nitride-containing material such as a titanium nitride (TiN) and/or titanium oxynitride (TiOₓN_{y}), which promotes or facilitates lattice matching through chemical bonding between the bottom electrode layer 236 and the buffer layer 238.

In implementations in which the insulator layer 240 includes an oxygen-containing material or an oxide-containing material such as aluminum oxide or zirconium oxide, the material of the buffer layer 238 may also include an oxygen-containing material or an oxide-containing material such as a titanium oxide (TiOₓ such as TiO₂), which may promote or facilitate lattice matching between the buffer layer 238 and the insulator layer 240.

A surface treatment operation may be performed on the bottom electrode layer 236 using a surface treatment chemical. The surface treatment chemical may include nitrous oxide (N₂O) and/or another type of surface treatment chemical that reacts with the material of the bottom electrode layer 236. The surface treatment operation forms the buffer layer 238 in and/or on the bottom electrode layer 236. In particular, the nitrous oxide (N₂O) of the surface treatment chemical may react with, for example, titanium nitride (e.g., TiₓN such as Ti₂N) in the bottom electrode layer 236 to form a buffer layer 238 including titanium oxide (e.g., TiOₓ such as TiO₂) and titanium nitride (TiN). The reaction between the material of the bottom electrode layer 236 and the nitrous oxide (N₂O) of the surface treatment chemical may include:

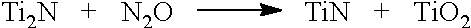

where the titanium nitride (e.g., TiₓN such as Ti₂N) in the bottom electrode layer 236 reacts with the nitrous oxide (N₂O) of the surface treatment chemical to form titanium oxide (e.g., TiOₓ such as TiO₂) and titanium nitride (TiN) in the buffer layer 238. An additional reaction of nitrous oxide (N₂O) with titanium oxide may also form titanium oxynitride (TiOₓN_{y}) to be a component of the buffer layer 238.

The insulator layer 240 includes an amorphous mixture or composition of a plurality of materials, and is overall an electrically insulating layer. As used herein, the term “amorphous” refers to a mixture or composition of molecules and atoms, where the molecules and atoms are in a variable arrangement. In other words, the molecules and atoms of an amorphous structure are in a non-crystalline unordered arrangement. Although there may be a short range of ordered molecules and atoms in the amorphous composition, the amorphous composition as a whole lacks a regular order of its elements. In some implementations, the amorphous composition is a non-ordered structure including oxygen and one or more metals (e.g., aluminum and/or zirconium). In some portions of the amorphous composition, the metals may be bonded to oxygen in the form of metal oxides (e.g., high-k metal oxides). For example, the amorphous composition may include a non-crystalline composition containing two or more high-k dielectric oxide materials such as zirconium oxide (ZrOₓ such as ZrO₂) and aluminum oxide (AlₓO_{y} such as Al₂O₃).

In some implementations, the insulator layer 240 includes an amorphous composition of zirconium, aluminum, and oxygen (ZrAlO). In the amorphous composition of zirconium, aluminum, and oxygen, there may be molecules with Zr—O bonds, Al—O bonds, Zr—O—Al bonds, and/or Zr—Al bonds in an amorphous thin film. For example, the insulator layer 240 may be an amorphous thin film including a non-crystalline composition containing two or more high-k oxides such as zirconium oxide (ZrOₓ such as ZrO₂) and aluminum oxide (AlₓO_{y} such as Al₂O₃).

In some implementations, the trench capacitor structure 226 includes a plurality of trenches 232, and the MIM structure of the trench capacitor structure 226 (e.g., the bottom electrode layer 236, the insulator layer 240, and the top electrode layer 242) may extend along the sidewalls and bottom surfaces of the plurality of trenches 232, and between the plurality of trenches 232. The trenches 232 may be laterally arranged and spaced apart by a distance (indicated in FIG. 2B as dimension D1) in the x-direction. In this way, including a plurality of trenches 232 in the trench capacitor structure 226 enables the length (and therefore the area) of the MIM structure of the trench capacitor structure 226 (e.g., of the bottom electrode layer 236, the insulator layer 240, and the top electrode layer 242) to be extended, thereby increasing the capacitance of the trench capacitor structure 226.

As further shown in FIG. 2B, the trench capacitor structure 226 may include one or more capping layers above the trench(es) 232 and above the MIM structure of the trench capacitor structure 226. The one or more capping layers may include an oxide capping layer 244, an oxynitride capping layer 246, and/or a nitride capping layer 248, among other examples. The capping layers may provide electrical isolation for the MIM structure of the trench capacitor structure 226, and/or may also function as a hard mask layer stack for forming the top contact 230. The oxide capping layer 244 may include an oxide-containing dielectric material such as silicon oxide (SiOₓ such as SiO₂), among other examples. The oxynitride capping layer 246 may include an oxynitride-containing dielectric material such as silicon oxynitride (SiON), among other examples. The nitride capping layer 248 may include a nitride-containing dielectric material such as silicon nitride (SiₓN_{y} such as Si₃N₄), among other examples.

As further shown in FIG. 2B, the trench capacitor structure 226 may include one or more sidewall spacers 250 and/or 252 on the sidewalls of the capping layers 244-248 and/or on sidewalls of the top electrode layer 242 that is above the trench(es) 232. The combination of the capping layers 244-248 and the sidewall spacers 250 and 252 may be used as a self-aligned mask when etching the adhesion layer 234, the bottom electrode layer 236, the buffer layer 238, the insulator layer 240, and/or the top electrode layer 242 to define the MIM structure of the trench capacitor structure 226. The sidewall spacer 250 may include an oxide-containing dielectric material such as silicon oxide (SiOₓ such as SiO₂), among other examples. The sidewall spacer 252 may include a nitride-containing dielectric material such as silicon nitride (SiₓN_{y} such as Si₃N₄), among other examples.

As indicated above, FIGS. 2A and 2B are provided as an example. Other examples may differ from what is described with regard to FIGS. 2A and 2B.

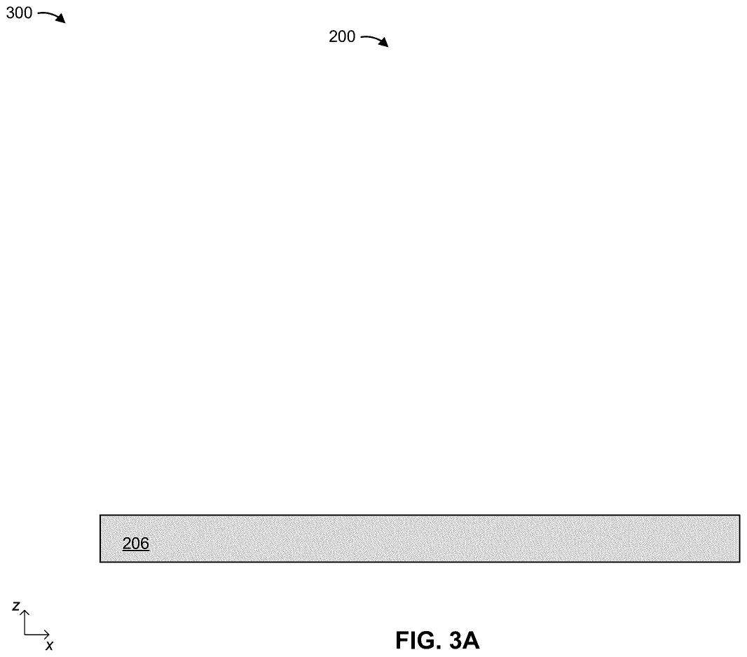

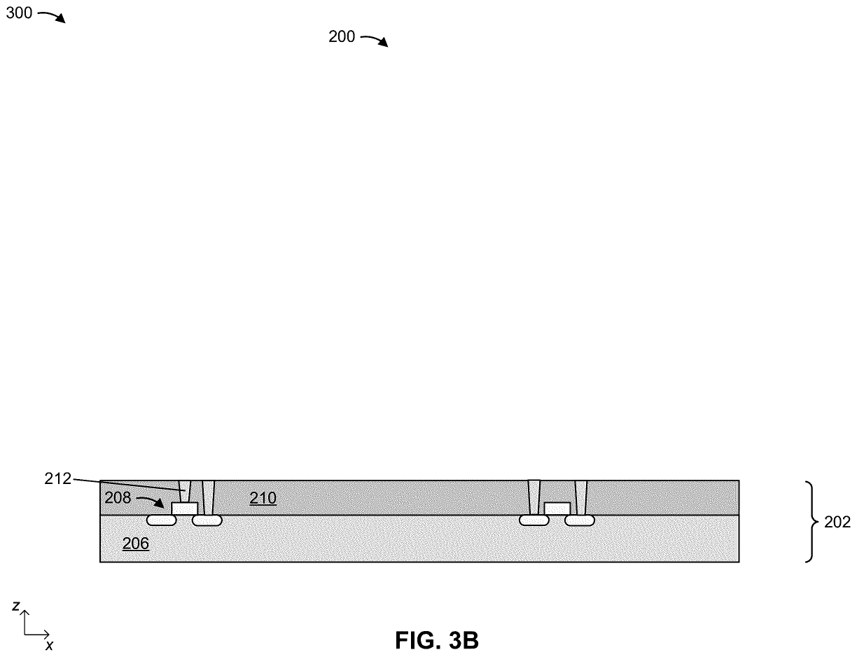

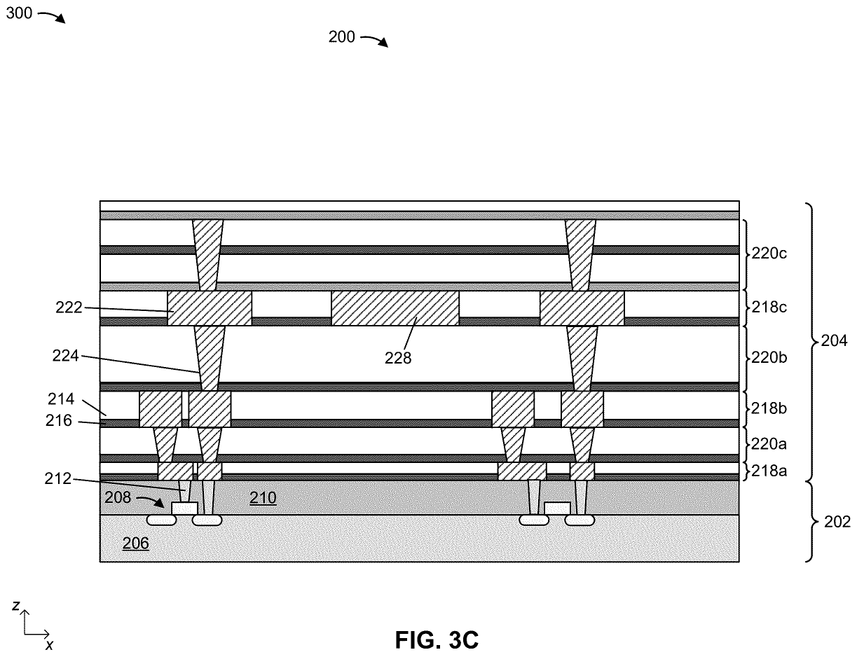

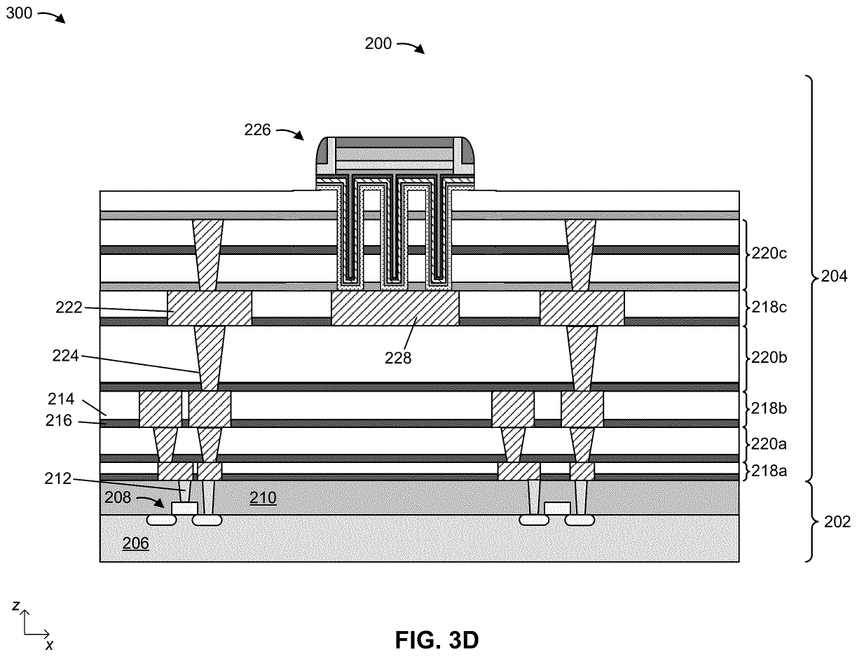

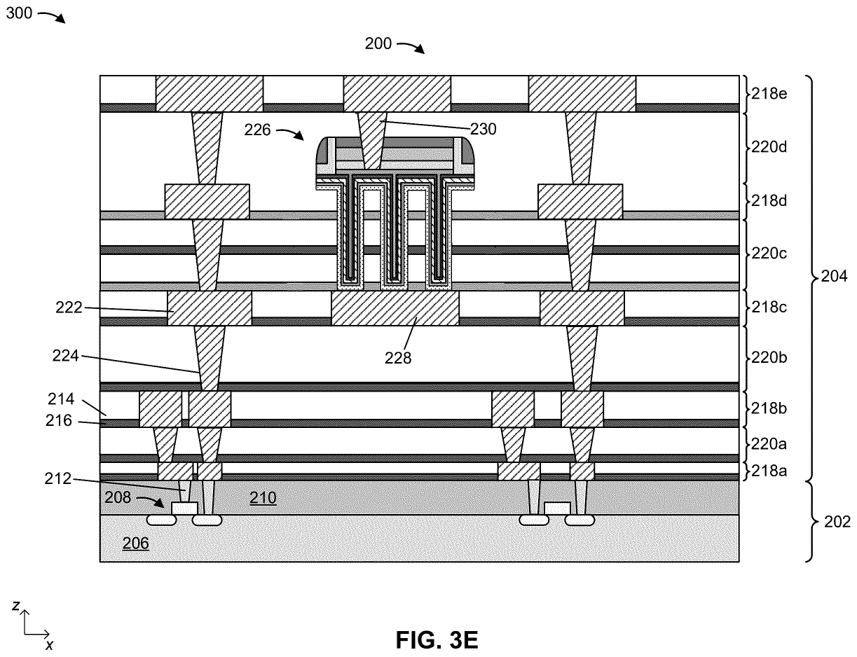

FIGS. 3A-3E are diagrams of an example implementation 300 of forming the semiconductor device 200 described herein. In some implementations, one or more of the semiconductor processing operations described in connection with FIGS. 3A-3E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 3A, the substrate 206 is provided. The substrate 206 may be provided in the form of a semiconductor wafer such as a silicon (Si) wafer, an SOI wafer, and/or another type of semiconductor work piece. The semiconductor device 200 may be formed on the semiconductor wafer with other semiconductor devices.

As shown in FIG. 3B, the integrated circuit devices 208 may be formed in and/or on the substrate 206 in the device layer 202 of the semiconductor device 200. One or more semiconductor processing tools may be used to form one or more portions of the integrated circuit devices 208. For example, an ion implantation tool may be used to dope one or more regions in the substrate 206 with one or more types of dopants to form well regions, implant regions, and/or other types of doped regions in the substrate 206 for the integrated circuit devices 208. As another example, a deposition tool may be used to perform various deposition operations to deposit layers and/or structures of the integrated circuit devices 208, and/or to deposit photoresist layers for etching the substrate 206 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 206 and/or portions of the deposited layers to form the integrated circuit devices 208. As another example, a planarization tool may be used to planarize portions of the integrated circuit devices 208. As another example, a plating tool may be used to deposit metal structures and/or layers of the integrated circuit devices 208.

As further shown in FIG. 3B, a deposition tool is used to deposit the dielectric layer 210 over and/or on the substrate 206 and over and/or on the integrated circuit devices 208. A deposition tool may be used to deposit the dielectric layer 210 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 210 after the dielectric layer 210 is deposited.

As further shown in FIG. 3B, the contacts 212 of the integrated circuit devices 208 may be formed through the dielectric layer 210. The contacts 212 may be formed in recesses in the dielectric layer 210. In some implementations, a pattern in a photoresist layer is used to etch the dielectric layer 210 to form the recesses. In these implementations, a deposition tool may be used to form the photoresist layer on the dielectric layer 210. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 210 based on a pattern to form the recesses.

The contacts 212 may be formed in the recesses. In some implementations, a contact 212 (e.g., a gate contact) is formed on a gate structure of an integrated circuit device 208. In some implementations, a contact 212 (e.g., a source/drain contact) is formed on a source/drain region of an integrated circuit device 208. A deposition tool may be used to deposit the material of the contacts 212 in the recesses using a CVD technique, a PVD technique, an ALD technique, an electroplating technique, and/or another suitable deposition technique. The material of the contacts 212 may be deposited in one or more deposition operations. In some implementations, a seed layer is first deposited, and the material of the contacts 212 is deposited on the seed layer. In some implementations, a planarization tool is used to perform a planarization operation (e.g., a CMP operation) to planarize the contacts 212 after the contacts 212 are deposited such that the tops of the contacts 212 are approximately co-planar with the top of the dielectric layer 210.

As shown in FIG. 3C, a first portion of the interconnect layer 204 of the semiconductor device 200 is formed above the dielectric layer 210. One or more deposition tools are used to deposit alternating layers of ILD layers 214 and ESLs 216 in the first portion of the interconnect layer 204 of the semiconductor device 200. In this way, the ILD layers 214 and ESLs 216 may be arranged in the z-direction in the semiconductor device 200. One or more deposition tools may be used to deposit each of the ILD layers 214 and each of the ESLs 216 using a PVD technique, an ALD technique, a CVD technique, an oxidation technique, and/or another suitable deposition technique. In some implementations, a planarization tool may be used to planarize the ILD layers 214 and/or the ESLs 216 after the ILD layers 214 and/or the ESLs 216 are deposited.

As further shown in FIG. 3C, a deposition tool, an exposure tool, a developer tool, an etch tool, a planarization tool, a plating tool, and/or another semiconductor processing tool may be used to perform various operations to form the metallization structures 222 and to form the interconnect structures 224 in the first portion of the interconnect layer 204 of the semiconductor device 200. The bottom contact 228 of the trench capacitor structure 226 may also be formed in the first portion of the interconnect layer 204.

In some implementations, the first portion of the interconnect layer 204 may be formed in a plurality of layers. For example, an ILD layer 214 and an ESL 216 may be formed (e.g., using one or more deposition tools and/or one or more planarization tools), recesses may be formed in and/or through the ILD layer 214 and the ESL 216 (e.g., using an exposure tool, a developer tool, and/or an etch tool), and the layer 218a (e.g., the M0 layer) of metallization structures 222 may be formed in the ILD layer 214 and the ESL 216 (e.g., using one or more deposition tools and/or one or more planarization tools). Another ILD layer 214 and another ESL 216 may be formed, and the layer 220a (e.g., the V0 layer) of interconnect structures 224 may be formed in the ILD layer 214 and the ESL 216. The layers 218b, 218c, 220b, and 220c may be formed in a similar manner.

One or more deposition tools may be used to deposit the metallization structures 222, the interconnect structures 224, and/or the bottom contact 228 using a PVD technique, an ALD technique, a CVD technique, an electroplating technique (e.g., an electro-chemical plating technique), and/or another suitable deposition technique. In some implementations, a planarization tool may be used to planarize the metallization structures 222, the interconnect structures 224, and/or the bottom contact 228 after the metallization structures 222, the interconnect structures 224, and/or the bottom contact 228 are deposited.

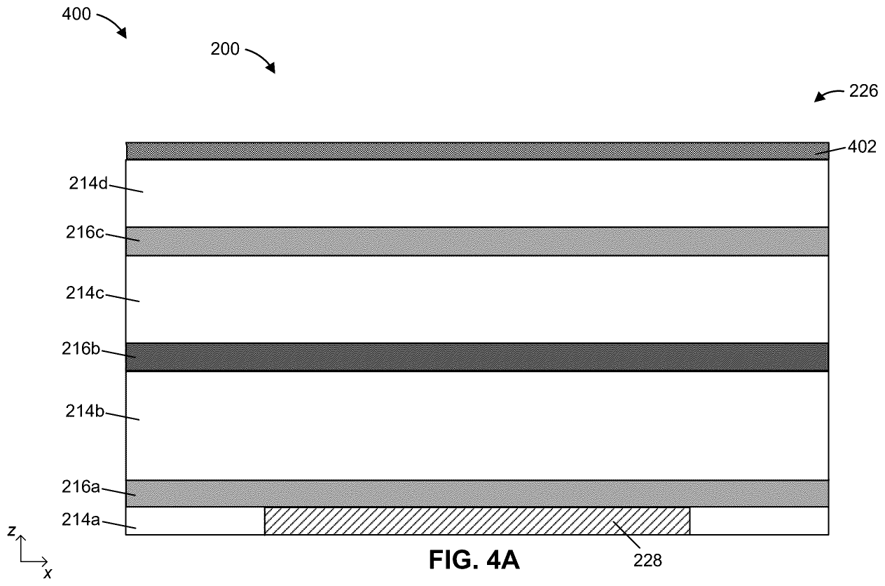

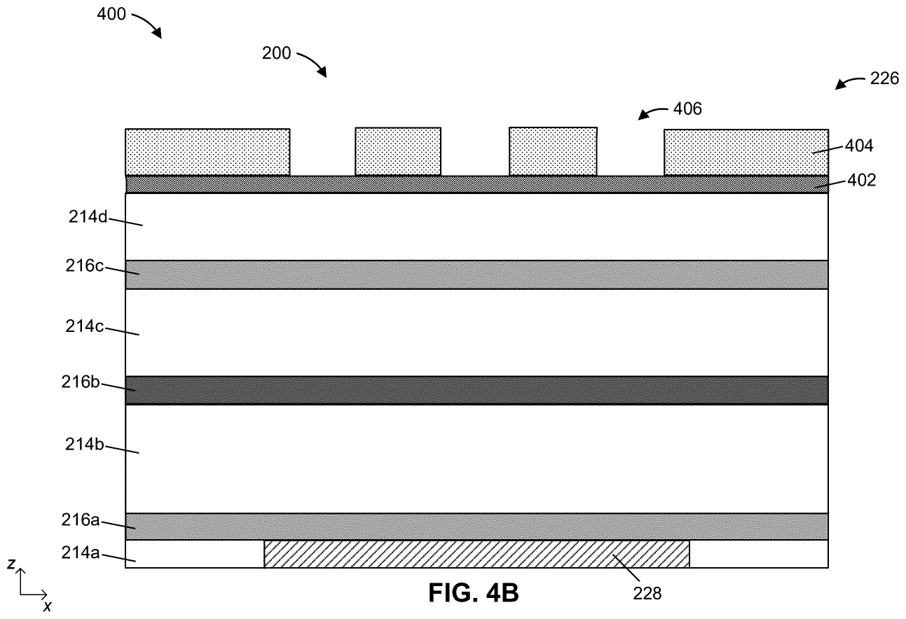

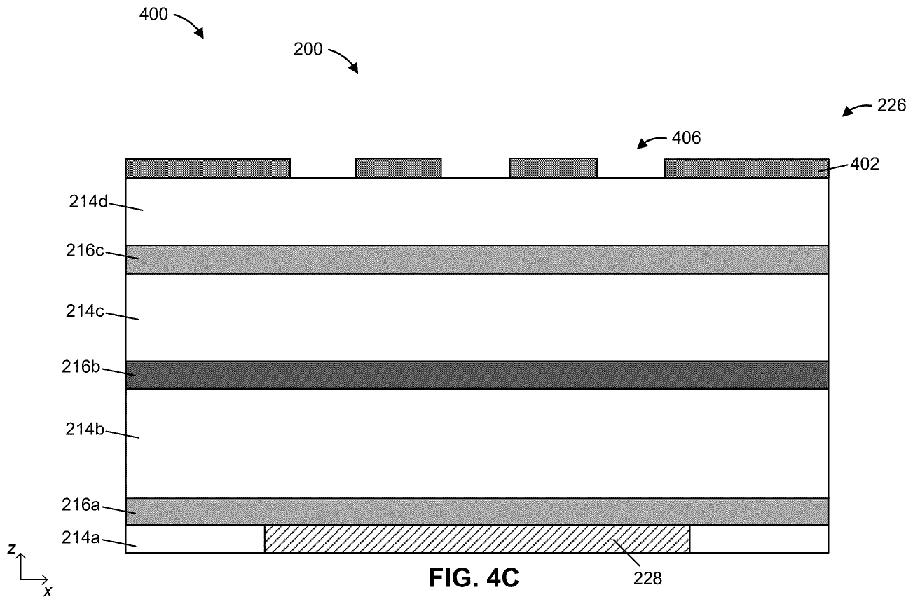

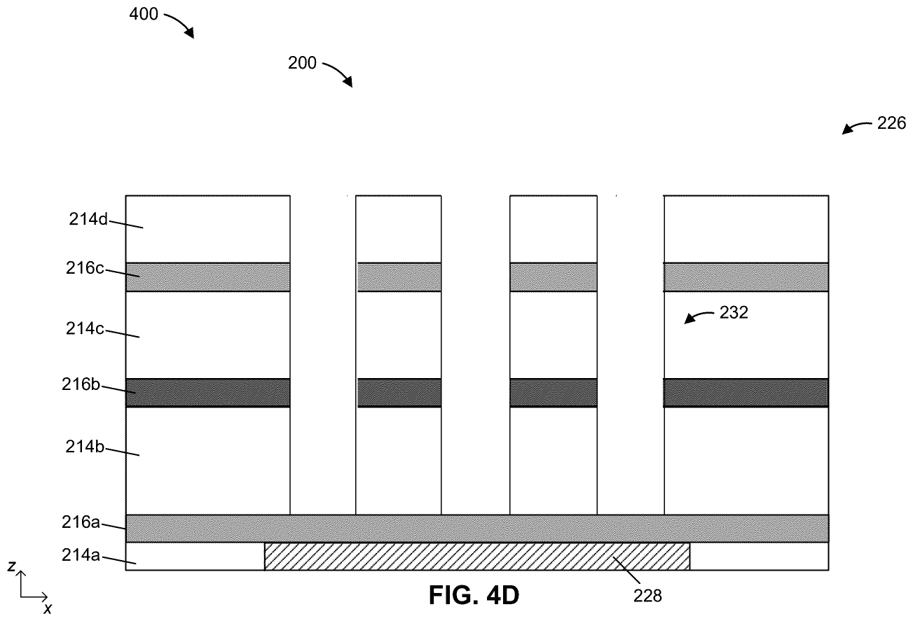

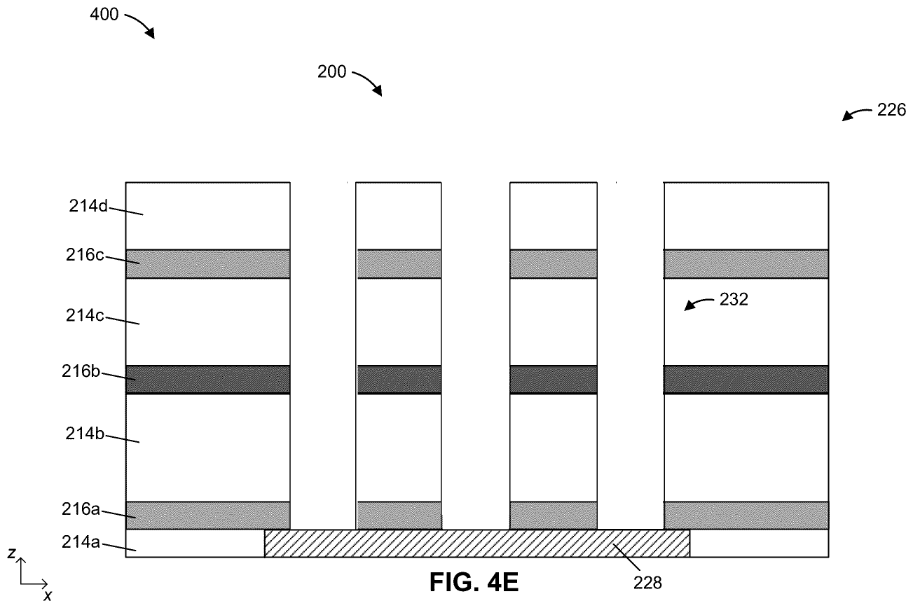

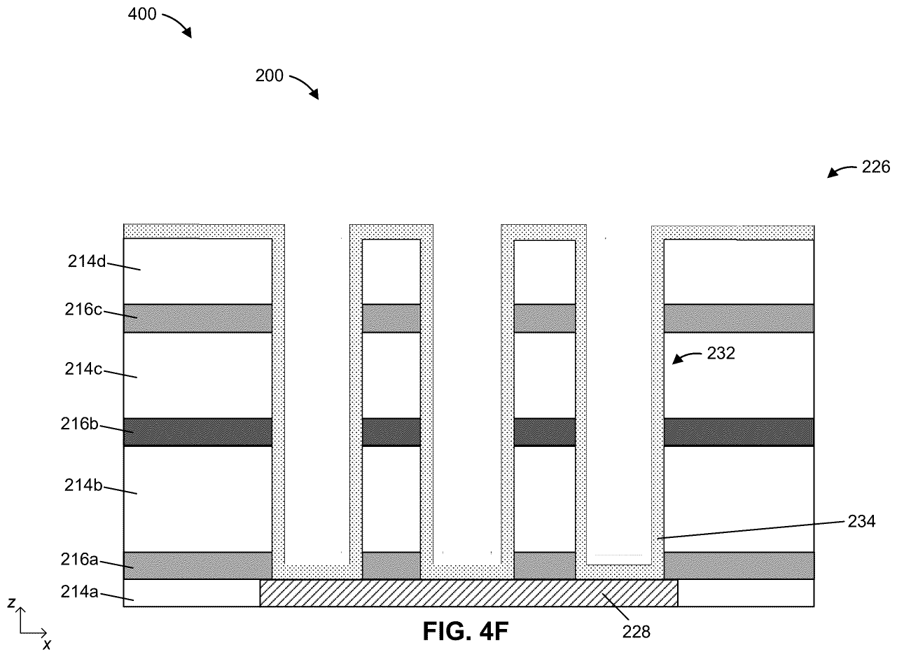

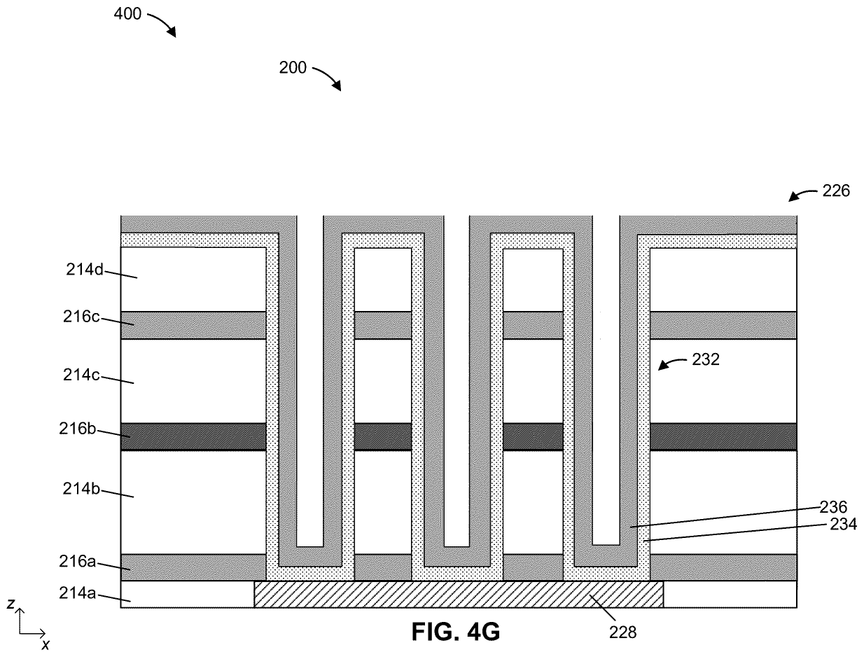

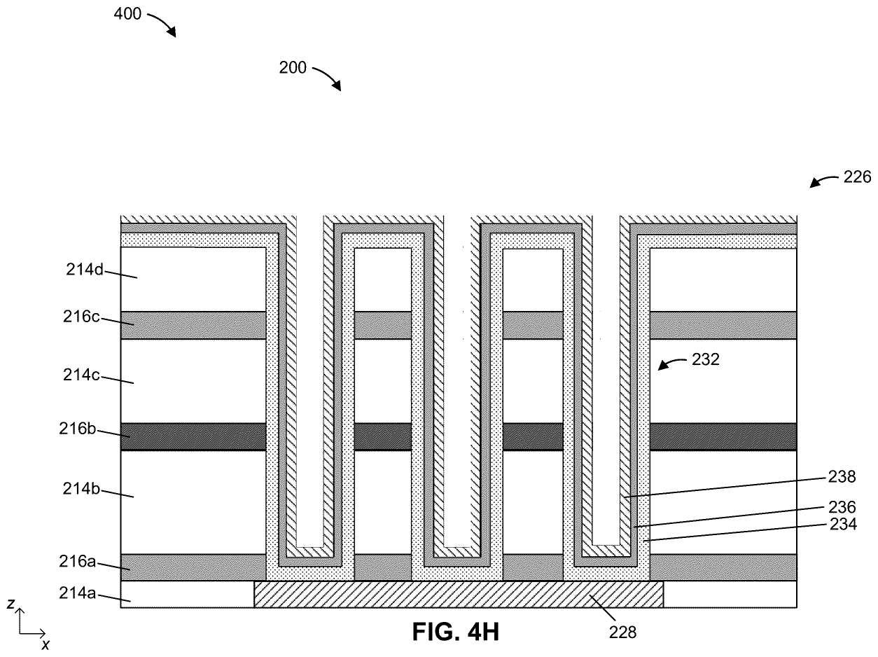

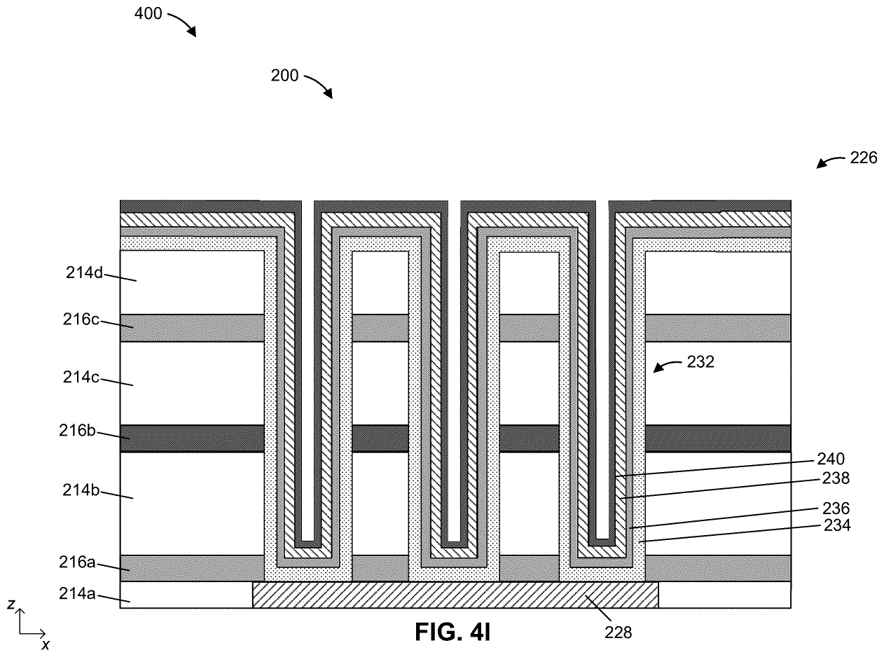

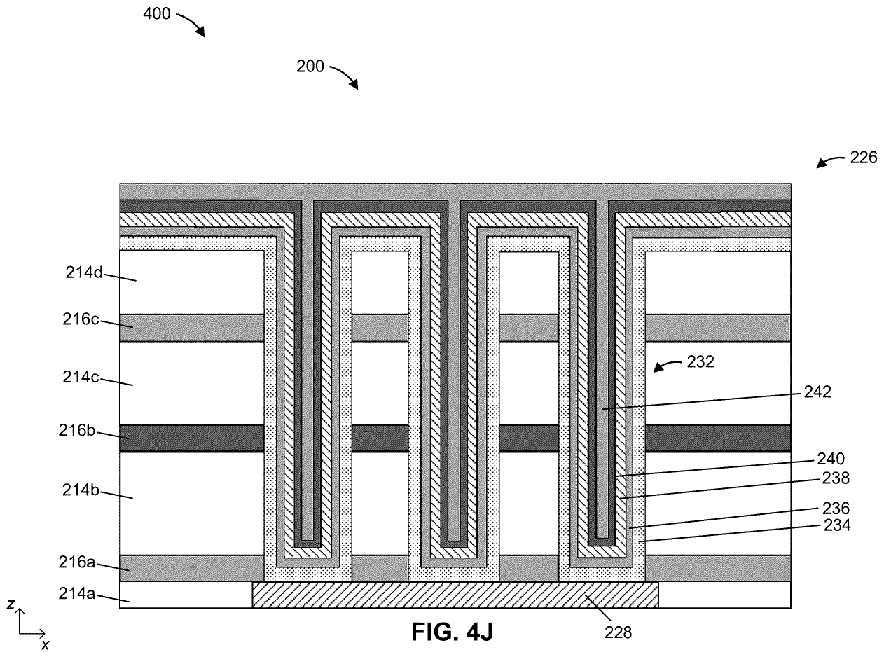

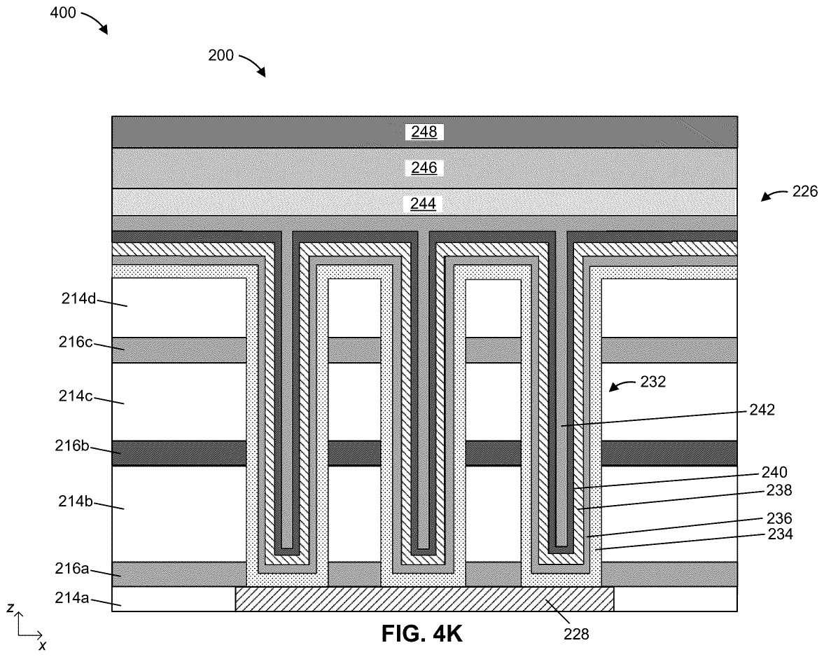

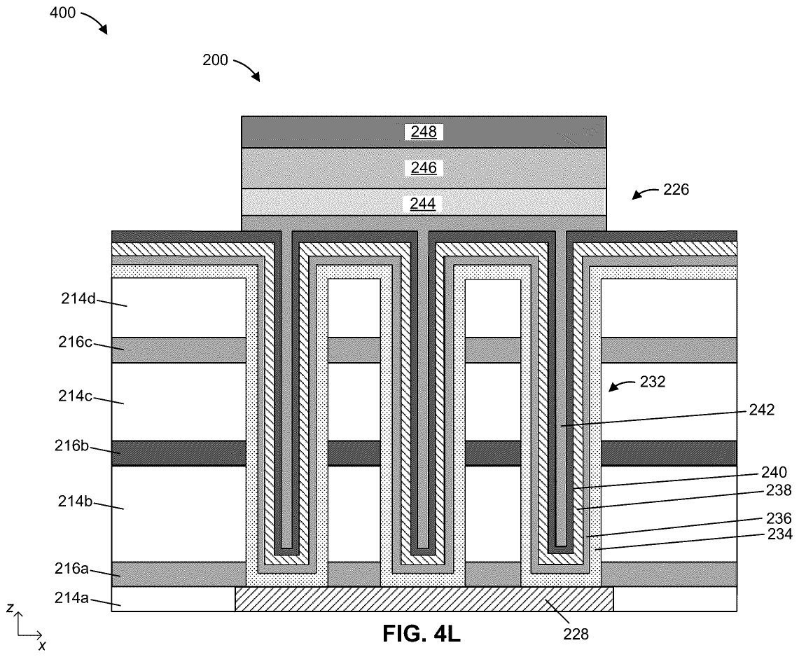

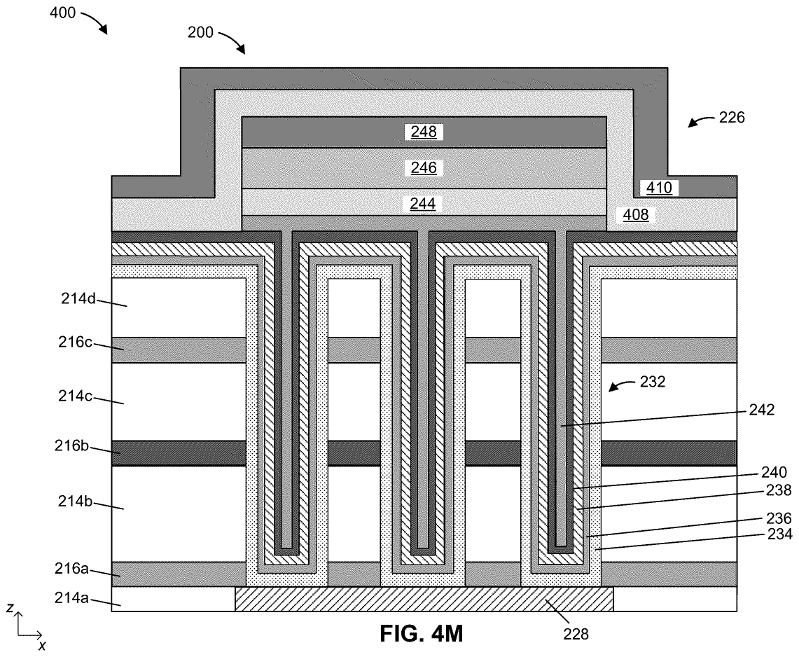

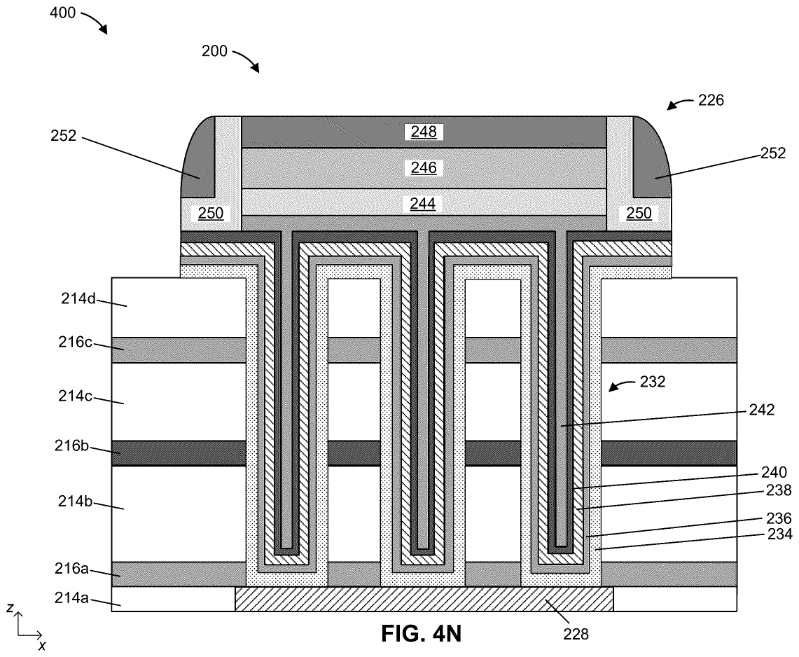

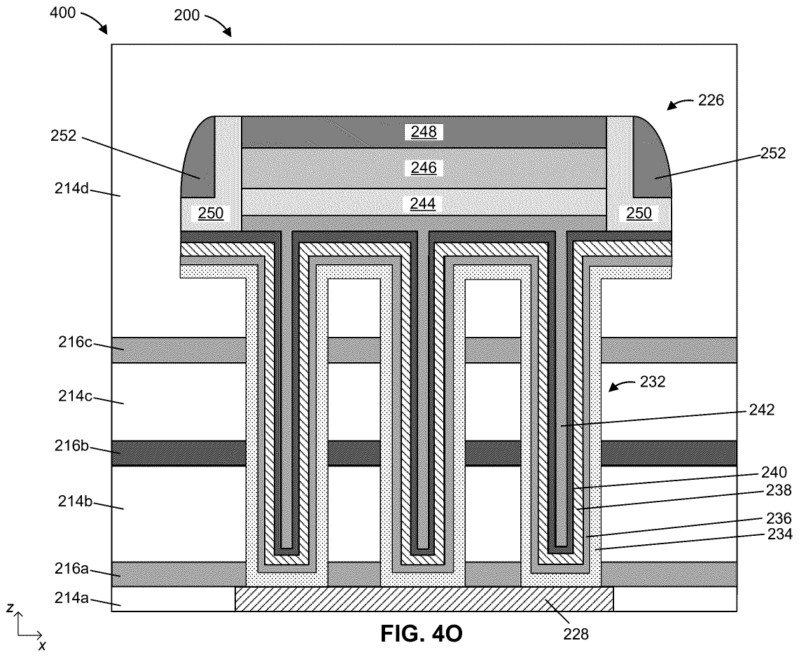

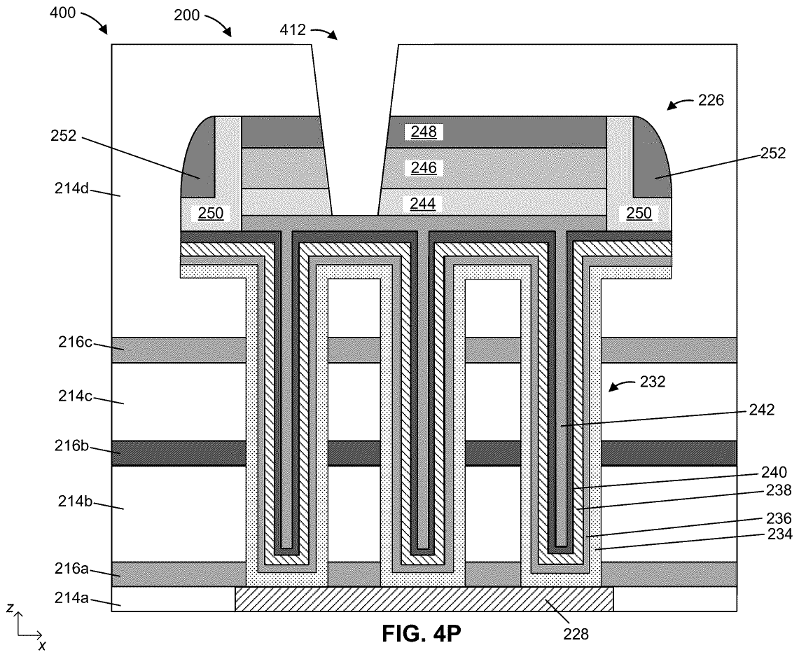

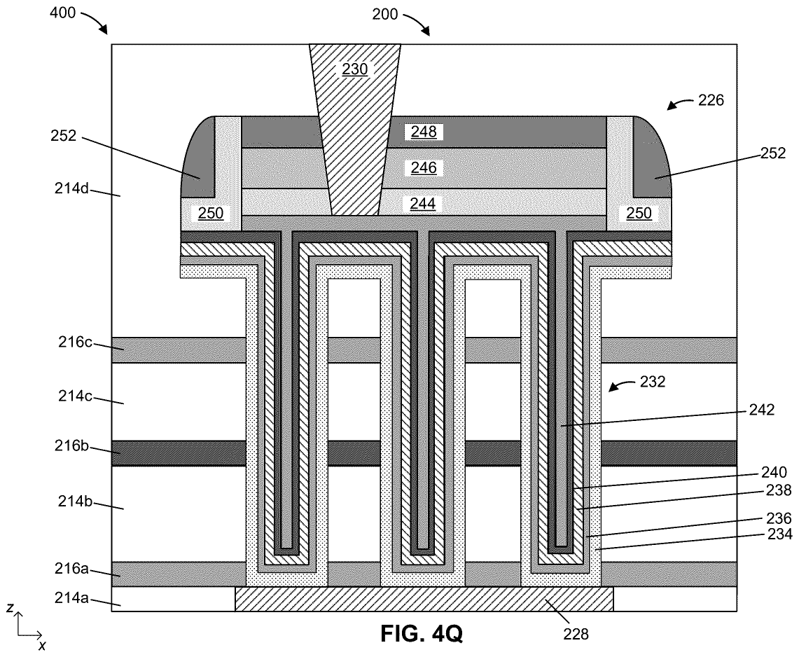

As shown in FIG. 3D, a trench capacitor structure 226 may be formed in one or more dielectric layers in the interconnect layer 204. The trench capacitor structure 226 may be formed such that the trench(es) 232 of the trench capacitor structure 226 land on the bottom contact 228 in the interconnect layer 204. An example process for forming the trench capacitor structure 226 is illustrated and described in connection with FIGS. 4A-4Q.

As shown in FIG. 3E, a second portion of the interconnect layer 204 of the semiconductor device 200 is formed above the first portion of the interconnect layer 204, including above the trench capacitor structure 226. The second portion of the interconnect layer 204 may be formed in a similar manner as the first portion of the interconnect layer 204 as described in connection with FIG. 3C. The top contact 230 of the trench capacitor structure 226 may be formed in the second portion of the interconnect layer 204.

As indicated above, FIGS. 3A-3E are provided as an example. Other examples may differ from what is described with regard to FIGS. 3A-3E.

FIGS. 4A-4Q are diagrams of an example implementation 400 of forming a trench capacitor structure 226 described herein. In some implementations, one or more of the semiconductor processing operations described in connection with FIGS. 4A-4Q may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 4A-4Q may be performed as part of the process for forming the semiconductor device 200 described in connection with FIGS. 3A-3E.

As shown in FIG. 4A, masking layers may be formed on the ILD layer 214d in the interconnect layer 204 of the semiconductor device 200. For example, a dielectric masking layer 402 may be formed on the ILD layer 214d. The dielectric masking layer 402 may include a silicon oxynitride material (SiON) and/or another suitable dielectric material.

A deposition tool may be used to deposit the dielectric masking layer 402 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 402 after the dielectric masking layer 402 is deposited.

As shown in FIG. 4B, a photoresist layer 404 may be formed above the dielectric masking layer 402, and a pattern 406 may be formed in the photoresist layer 404. A deposition tool may be used to form the photoresist layer on the dielectric masking layer 402 (e.g., using a spin-coating technique or another suitable deposition technique). In some implementations, a bottom antireflective coating (BARC) is first deposited on the dielectric masking layer 402, and then the photoresist layer 404 is deposited onto the BARC. An exposure tool may be used to expose the photoresist layer 404 to a radiation source to pattern the photoresist layer 404. A developer tool may be used to develop and remove portions of the photoresist layer 404 to expose the pattern 406.

As shown in FIG. 4C, an etch tool may be used to etch the dielectric masking layer 402 based on the pattern 406 in the photoresist layer 404, to transfer the pattern 406 to the dielectric masking layer 402. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 402 compared to the material of the underlying ILD layer 214d. Thus, the etch operation may stop on the ILD layer 214d with minimal etching to the ILD layer 214d.

As shown in FIG. 4D, another etch operation is performed to etch through the ILD layers 214b, 214c, 214d, and through the ESLs 216b and 216c to form the trench(es) 232 of the trench capacitor structure 226. The etch operation may include, for example, a gas-based etch operation in which a different type of etchant is used, as compared to the etchant that was used to transfer the pattern 406 to the dielectric masking layer 402. Thus, the semiconductor device 200 may be transferred from a first etch tool (in which the pattern 406 was transferred to the dielectric masking layer 402) to a second etch tool (in which the ILD layers 214b, 214c, 214d, and the ESLs 216b and 216c are etched) using a wafer/die transport tool to reduce the likelihood of cross-contamination between the first and second etch tools. Alternatively, an etch tool that has multiple processing chambers (e.g., a cluster tool) may be used, and the semiconductor device 200 may be transferred between processing chambers of the etch tool for etching using different types of etchants.

The gas-based etchant that is used to etch the ILD layers 214b, 214c, 214d, and the ESLs 216b, 216c, may include a fluorine-based gas etchant that has a higher etch rate for the dielectric materials of the ILD layers 214b, 214c, 214d, and the ESLs 216b, 216c, compared to the etch rate of the dielectric masking layer 402. This enables the ILD layers 214b, 214c, 214d, and the ESLs 216b, 216c, to be etched with minimal etching to the dielectric masking layer 402 (and thus, minimal to no increase in the width or critical dimension at the tops of the trench(es) 232). The fluorine-based etchant may include a carbon fluoride-based (CFₓ) gas etchant such as a carbon tetrafluoride (CF₄) gas etchant.

In some implementations, a plurality of etch operations (e.g., a plurality of gas-based etch operations using the fluorine-based etchant) are performed to form the trench(es) 232 of the trench capacitor structure 226. For example, a first etch operation (referred to as a “main etch” operation) may be performed to form the trench(es) 232 to the ESL 216a. In other words, etching in the first etch operation stops at the ESL 216a such that the ESL 216a remains between the bottom of the trench(es) 232 and the underlying bottom contact 228. The ESL 216a is kept over the bottom contact 228 to prevent the bottom contact 228 from being exposed to oxygen and other contaminants that might otherwise result in oxidation of the bottom contact 228. After the first etch operation, the trench(es) 232 may have tapered sidewalls, resulting in the lateral width of the trench(es) 232 decreasing from the tops of the trench(es) 232 to the bottoms of the trenches.

A second etch operation (referred to as an “over etch” operation) may be performed after the first etch operation to shape the bottom portions of the trench(es) 232. In particular, the second etch operation may be performed to increase the verticality of the sidewalls of the trench(es) 232, thereby lessening the taper in the sidewalls of the trench(es) 232. The dielectric masking layer 402 remains on the ILD layer 214d during the first and second etch operations to form and shape the trench(es) 232 such that the dielectric masking layer 402 protects the ILD layer 214d from being etched, which reduces the likelihood of critical dimension widening and reduces the likelihood of corner rounding at the tops of the trench(es) 232.

As shown in FIG. 4E, a third etch operation (referred to as a “linear removal” etch operation) is performed to etch through the ESL 216a at the bottom of the trench(es) 232 to extend the trench(es) 232 through the ESL 216a and to the underlying bottom contact 228. Thus, the bottom contact 228 is exposed through the trench(es) 232 after the third etch operation. The third etch operation may be performed using the second etch tool and using a fluorine-based etchant such as a carbon fluoride-based (CFₓ such as CF₄) gas etchant. The dielectric masking layer 402 remains on the ILD layer 214d during the third etch operation to etch through the ESL 216a such that the dielectric masking layer 402 protects the ILD layer 214d from being etched, which reduces the likelihood of critical dimension reduction. Following exposure of the bottom contact 228 in the trench(es) 232, the dielectric masking layer 402 is removed from the ILD layer 214d.

As shown in FIG. 4F, the adhesion layer 234 may be deposited on the sidewalls and on the bottom surfaces of the trench(es) 232. The bottom surfaces of the trench(es) 232 correspond to the top surface of the bottom contact 228, and thus the adhesion layer 234 may be in physical contact with the top surface of the bottom contact 228. The adhesion layer 234 may also be deposited on the top surface of the ILD layer 214d between adjacent trenches 232 such that the adhesion layer 234 may be in physical contact with the top surface of the ILD layer 214d. In some implementations, a deposition tool is used to conformally deposit the adhesion layer 234 such that the adhesion layer 234 conforms to the profile of the trench(es) 232. In some implementations, a conformal CVD technique and/or an ALD technique is used to deposit the adhesion layer 234.

As shown in FIG. 4G, the bottom electrode layer 236 may be deposited on the adhesion layer 234. Thus, the bottom electrode layer 236 is deposited on the sidewalls and on the bottom surfaces (which correspond to the top surface of the bottom contact 228) of the trench(es) 232. The bottom electrode layer 236 may also be deposited on the top surface of the adhesion layer 234 between adjacent trenches 232. In some implementations, a deposition tool is used to conformally deposit the bottom electrode layer 236 such that the bottom electrode layer 236 conforms to the profile of the trench(es) 232. In some implementations, a conformal CVD technique and/or an ALD technique is used to deposit the bottom electrode layer 236.

As shown in FIG. 4H, a surface treatment operation is performed on the bottom electrode layer 236 using a surface treatment chemical. The surface treatment chemical may include nitrous oxide (N₂O) and/or another type of surface treatment chemical that reacts with the material of the bottom electrode layer 236. The surface treatment operation forms the buffer layer 238 in and/or on the bottom electrode layer 236. As a result, an outer portion of the bottom electrode layer 236 exposed to the nitrous oxide (N₂O) is converted to the buffer layer 238. The nitrous oxide (N₂O) of the surface treatment chemical reacts with, for example, titanium nitride (e.g., TiₓN such as Ti₂N) in the bottom electrode layer 236 to form the buffer layer 238 including titanium oxide (e.g., TiOₓ such as TiO₂) and titanium nitride (TiN). An additional reaction of nitrous oxide (N₂O) with titanium oxide may also form titanium oxynitride (TiOₓN_{y}) to be a component of the buffer layer 238.

As shown in FIG. 4I, the insulator layer 240 may be deposited on the buffer layer 238. Thus, the insulator layer 240 is deposited on the sidewalls and on the bottom surfaces (which correspond to the top surface of the bottom contact 228) of the trench(es) 232. The insulator layer 240 may also be deposited on the top surface of the buffer layer 238 between adjacent trenches 232. In some implementations, a deposition tool is used to conformally deposit the insulator layer 240 such that the insulator layer 240 conforms to the profile of the trench(es) 232. In some implementations, a conformal CVD technique and/or an ALD technique is used to deposit the insulator layer 240.

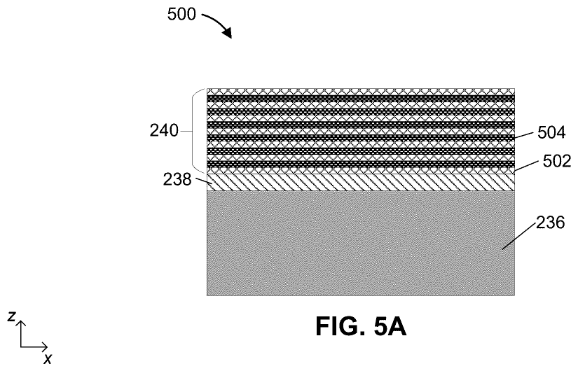

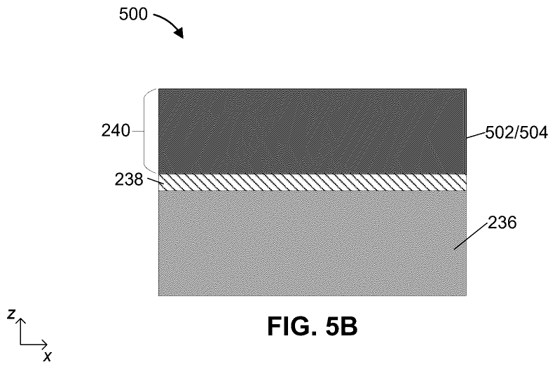

In some implementations, a plurality of ALD cycles are performed to deposit the insulator layer 240. As described in more detail in connection with FIG. 5A, performing an ALD cycle may include depositing, using a first material precursor, zirconium oxide (ZrOₓ such as ZrO₂), and depositing, using a second material precursor, aluminum oxide (AlₓO_{y} such as Al₂O₃) on the zirconium oxide. The first material precursor is oxidized to form the zirconium oxide, and the second material precursor is oxidized to form the aluminum oxide. The plurality of ALD cycles are performed to deposit alternating atomic layers of zirconium oxide and aluminum oxide. The alternating atomic layers of zirconium oxide and aluminum oxide blend together to form the insulator layer 240. The insulator layer 240 includes an amorphous composition of zirconium, aluminum, and oxygen (ZrAlO) where there may be molecules with Zr—O bonds, Al—O bonds, Zr—O—Al bonds, and/or Zr—Al bonds in an amorphous thin film. The insulator layer 240 may be an amorphous thin film including a non-crystalline composition containing zirconium oxide and aluminum oxide.

As shown in FIG. 4J, the top electrode layer 242 may be deposited on the insulator layer 240. The top electrode layer 242 may be deposited such that the top electrode layer 242 fills the remaining areas of the trench(es) 232. The top electrode layer 242 may also be deposited on the top surface of the insulator layer 240 between adjacent trenches 232. In some implementations, a deposition tool is used to conformally deposit the top electrode layer 242 using a PVD technique, a CVD technique, an ALD technique, and/or another suitable deposition technique.

As shown in FIG. 4K, capping layers are formed above the trenches 232 of the trench capacitor structure 226. For example, the oxide capping layer 244 may be formed above and/or on the top electrode layer 242, the oxynitride capping layer 246 may be formed above and/or on the oxide capping layer 244, and/or the nitride capping layer 248 may be formed above and/or on the oxynitride capping layer 246, among other examples.

A deposition tool may be used to deposit the oxide capping layer 244, the oxynitride capping layer 246, and/or the nitride capping layer 248 using a PVD technique, an ALD technique, a CVD technique, an oxidation technique, and/or another suitable deposition technique. The oxide capping layer 244, the oxynitride capping layer 246, and/or the nitride capping layer 248 may be deposited in one or more deposition operations. In some implementations, a planarization tool may be used to perform a planarization operation (e.g., a CMP operation) to planarize the oxide capping layer 244, the oxynitride capping layer 246, and/or the nitride capping layer 248 after the oxide capping layer 244, the oxynitride capping layer 246, and/or the nitride capping layer 248 are deposited.

As shown in FIG. 4L, the capping layers (e.g., the oxide capping layer 244, the oxynitride capping layer 246, and/or the nitride capping layer 248) may be used to etch and define the top electrode layer 242 of the trench capacitor structure 226. In some implementations, a pattern in a photoresist layer is used to etch the oxide capping layer 244, the oxynitride capping layer 246, and/or the nitride capping layer 248 to form a hard mask over the top electrode layer 242. In these implementations, a deposition tool may be used to form the photoresist layer on the nitride capping layer 248. An exposure tool may be used to expose the photoresist layer to a radiation source to pattern the photoresist layer. A developer tool may be used to develop and remove portions of the photoresist layer to expose the pattern. An etch tool may be used to etch the oxide capping layer 244, the oxynitride capping layer 246, and/or the nitride capping layer 248 based on the pattern to define the hard mask layer. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). An etch tool may then be used to etch the top electrode layer 242 based on the hard mask layer (e.g., based on the pattern in the oxide capping layer 244, the oxynitride capping layer 246, and/or the nitride capping layer 248) to define the top electrode layer 242.

As shown in FIG. 4M, spacer layers 408 and 410 are formed above the capping layers (e.g., the oxide capping layer 244, the oxynitride capping layer 246, and/or the nitride capping layer 248). The spacer layers 408 and 410 extend along the ends of the capping layers (e.g., along the ends of the oxide capping layer 244, the ends of oxynitride capping layer 246, and/or the ends of the nitride capping layer 248) and along the ends of the top electrode layer 242. Moreover, the spacer layers 408 and 410 are formed on the exposed portions of the insulator layer 240.

A deposition tool may be used to deposit the spacer layers 408 and/or 410 using a PVD technique, an ALD technique, a CVD technique, an oxidation technique, and/or another suitable deposition technique. The spacer layers 408 and/or 410 may be deposited in one or more deposition operations. In some implementations, a planarization tool may be used to perform a planarization operation (e.g., a CMP operation) to planarize the spacer layers 408 and/or 410 after the spacer layers 408 and/or 410 are deposited.

As shown in FIG. 4N, the spacer layers 408 and 410 are etched along with portions of the insulator layer 240, portions of the buffer layer 238, portions of the bottom electrode layer 236, and portions of the adhesion layer 234 to define the bottom electrode layer 236 of the MIM structure of the trench capacitor structure 226. The etch operation may be referred to as a CBM etch operation. In some implementations, the etch operation includes a dry etch operation (e.g., a plasma-based etch operation, a gas-based etch operation), a wet chemical etch operation, and/or another type of etch operation. Etching of the spacer layers 408 and 410 removes portions of the spacer layers 408 and 410 from the top of the nitride capping layer 248, resulting in formation of the sidewall spacers 250 and 252 on the ends of the oxide capping layer 244, the ends of oxynitride capping layer 246, the ends of the nitride capping layer 248, and the ends of the top electrode layer 242. Moreover, etching of the spacer layers 408 and 410 results in the sidewall spacers 252 having rounded outer surfaces.

An etchant (e.g., a gas-based etchant, a plasma-based etchant) may be used to achieve an anisotropic etch of the spacer layers 408 and 410. The spacer layers 408 and 410 may be etched along with portions of the insulator layer 240, portions of the buffer layer 238, portions of the bottom electrode layer 236, and portions of the adhesion layer 234. The anisotropic etch primarily etches in the z-direction in the semiconductor device 200, enabling minimal lateral etching of the bottom electrode layer 236 and of the insulator layer 240 to be achieved.

As shown in FIG. 4O, additional material of the ILD layer 214d may be formed to encapsulate the trench capacitor structure 226. A deposition tool may be used to deposit the additional material of the ILD layer 214d using a PVD technique, an ALD technique, a CVD technique, an epitaxy technique, an oxidation technique, and/or another suitable deposition technique. The additional material of the ILD layer 214d may be deposited in one or more deposition operations. In some implementations, a planarization tool may be used to perform a planarization operation (e.g., a CMP operation) to planarize the ILD layer 214d after the additional material of the ILD layer 214d is deposited.

As shown in FIG. 4P, a recess 412 may be formed in the ILD layer 214d, through the capping layers 244-248, and to the top electrode layer 242 of the trench capacitor structure 226. Thus, the top electrode layer 242 may be exposed through the recess 412.

In some implementations, a pattern in a photoresist layer is used to etch the ILD layer 214d, the oxide capping layer 244, the oxynitride capping layer 246, and/or the nitride capping layer 248 to form the recess 412. In these implementations, a deposition tool may be used to form the photoresist layer on the ILD layer 214d. An exposure tool may be used to expose the photoresist layer to a radiation source to pattern the photoresist layer. A developer tool may be used to develop and remove portions of the photoresist layer to expose the pattern. An etch tool may be used to etch the ILD layer 214d, the oxide capping layer 244, the oxynitride capping layer 246, and/or the nitride capping layer 248 based on the pattern to form the recess 412. In some implementations, one or more etch operations are performed to etch the ILD layer 214d, the oxide capping layer 244, the oxynitride capping layer 246, and/or the nitride capping layer 248. In some implementations, the one or more etch operations may include a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 412 based on a pattern.

As shown in FIG. 4Q, the top contact 230 may be formed in the recess 412. A deposition tool may be used to deposit the material of the top contact 230 using a CVD technique, a PVD technique, an ALD technique, an electroplating technique, and/or another suitable deposition technique. The top contact 230 may be deposited in one or more deposition operations. In some implementations, a seed layer is first deposited, and the top contact 230 is deposited on the seed layer. In some implementations, a planarization tool is used to perform a planarization operation (e.g., a CMP operation) to planarize the top contact 230 after the top contact 230 is deposited.

As indicated above, FIGS. 4A-4Q are provided as an example. Other examples may differ from what is described with regard to FIGS. 4A-4Q.

FIGS. 5A and 5B illustrate an example implementation 500 of the insulator layer 240 described herein. The example implementation 500 includes an example ALD technique in which alternating atomic layers of a zirconium oxide layer 502 and an aluminum oxide layer 504 are deposited on the buffer layer 238. The alternating atomic layers blend together to form the amorphous structure of the insulator layer 240. A plurality of operations in the ALD technique are performed as a function of time.

A plurality of ALD cycles are performed to form the insulator layer 240. An ALD cycle in the example implementation 500 includes the use of sequential gas-phase precursors (or reactants). The semiconductor device 200 is placed in a processing chamber of a deposition tool, and an oxygen-containing gas is pulsed in the ALD cycle to perform an oxygen treatment on the semiconductor device 200. The oxygen-containing gas may include ozone (O₃), oxygen (O₂), water vapor (H₂O), and/or another oxygen-containing gas. The duration of the pulse of the oxygen-containing gas may be included in a range of approximately 0.1 seconds to approximately 3 seconds. However, other values for the range are within the scope of the present disclosure.

The pulse of the oxygen-containing gas may be followed by a first pulse of a first metal material precursor, in which the first metal material precursor is provided to the processing chamber of the deposition tool. The first metal material precursor may include a zirconium gas-phase precursor for a zirconium oxide layer 502. Examples of zirconium precursors include zirconium(IV) tert-butoxide (Zr[OC(CH₃)₃]₄), zirconium (IV) iodide (ZrI₄), zirconium (IV) chloride (ZrCl₄), and tetrakis(dimethylamido)zirconium(IV) (Zr(NMe₂)₄), among other examples. The duration of the first pulse of the first metal material precursor may be included in a range of approximately 0.1 seconds to approximately 3 seconds. However, other values for the range are within the scope of the present disclosure.

The first metal material precursor is subsequently purged from the processing chamber, and another pulse of the oxygen-containing gas may be provided to the processing chamber. The pulse of the oxygen-containing gas may be followed by a pulse of a second metal material precursor, in which the second metal material precursor is provided to the processing chamber of the deposition tool. The second metal material precursor may include an aluminum gas-phase precursor for an aluminum oxide layer 504. Examples of aluminum precursors include trimethylaluminum (TMA) (C₃H₉Al), dimethylaluminum hydride (DMAH) ((CH₃)₂AlH), and dimethylethylamine alane (DMEAA) (AIH₃: N(CH₃)₂(CH₂CH₃)), among other examples. The duration of the pulse of the second metal material precursor may be included in a range of approximately 0.1 seconds to approximately 3 seconds. However, other values for the range are within the scope of the present disclosure.

The first pulse of the first metal material precursor may react with the oxygen-containing gas to form a first zirconium oxide layer 502 of the insulator layer 240. The first zirconium oxide layer 502 includes an oxygenized metal material (e.g., a metal oxide material) that includes the metal (e.g., zirconium) of the first metal material precursor. The first pulse of the second metal material precursor may react with the oxygen-containing gas to form a first aluminum oxide layer 504 of the insulator layer 240 on the first zirconium oxide layer 502. The first aluminum oxide layer 504 includes an oxygenized metal material (e.g., a metal oxide material) that includes the metal (e.g., aluminum) of the second metal material precursor.

Additional ALD cycles may be performed to form repeating alternate atomic layers (e.g., zirconium oxide layers 502 and aluminum oxide layers 504) on the first zirconium oxide layer 502 and the first aluminum oxide layer 504 as shown in FIG. 5A. The quantity of ALD cycles performed may be based on a thickness that is to be achieved for the insulator layer 240.

In some implementations, the plurality of ALD cycles are performed to deposit alternating atomic layers of zirconium oxide and aluminum oxide at the same or different deposition rates. In particular, atomic layers of a first high-k metal oxide (e.g., zirconium oxide) can be deposited at approximately the same rate as, a greater rate than, or a lesser rate than atomic layers of a second high-k metal oxide (e.g., aluminum oxide) in an ALD cycle.

In some implementations, the deposition rate for each ALD cycle is included in a range of approximately 0.5 angstroms per ALD cycle to approximately 2 angstroms per ALD cycle. However, other values for the range are within the scope of the present disclosure.

The time duration of each ALD cycle may be included in a range of approximately 3 seconds to approximately 6 seconds. However, other values for the range are within the scope of the present disclosure. In some implementations, the amount of time for the reaction of pulses of the first metal material precursor with the oxygen-containing gas and/or the amount of first metal material precursor is controlled to increase or decrease a concentration and/or a deposited thickness of the zirconium oxide layers 502. Similarly, the amount of time for the reaction of pulses of the second metal material precursor with the oxygen-containing gas and/or the amount of second metal material precursor is controlled to increase or decrease a concentration and/or a deposited thickness of the aluminum oxide layers 504.

In some implementations, one or more ALD cycles may each include a greater quantity of pulses of the first metal material precursor than the quantity of pulses of the second metal material precursor to achieve a higher concentration and higher deposited thicknesses of a first metal oxide (e.g., zirconium oxide) in the insulator layer 240. For example, an ALD cycle may include 3 pulses of zirconium and 1 pulse of aluminum to achieve a thickness ratio of a thickness of a zirconium oxide layer 502 to a thickness of an aluminum oxide layer 504 that is approximately 3:1.

Alternatively, one or more ALD cycles may each include a greater quantity of pulses of the second metal material precursor than the quantity of pulses of the first metal material precursor to achieve a higher concentration and higher deposited thicknesses of a second metal oxide (e.g., aluminum oxide) in the insulator layer 240. For example, an ALD cycle may include 3 pulses of zirconium and 4 pulses of aluminum to achieve a thickness ratio of a thickness of a zirconium oxide layer 502 to a thickness of an aluminum oxide layer 504 that is approximately 3:4.

In some implementations, one or more ALD cycles may include the same quantity of pulses for the first metal precursor and the second metal precursor to achieve approximately a same concentration and approximately a same deposited thickness of the first metal oxide and the second metal oxide. As used herein, “concentration” refers to a quantity of a given substance with respect to volume (e.g., atoms per cm³).

A combined deposited thickness of the zirconium oxide layers 502 in the z-direction can be greater than a combined deposited thickness of the aluminum oxide layers 504 in the z-direction, less than a combined deposited thickness of the aluminum oxide layers 504 in the z-direction, or approximately equal to a combined deposited thickness of the aluminum oxide layers 504 in the z-direction. The thicknesses of individual zirconium oxide layers 502 and aluminum oxide layers 504 in the z-direction can similarly be increased or decreased by varying reaction time and/or precursor amounts during a given ALD cycle.

In some implementations, the ALD cycles are repeated until the insulating layer 240 has a thickness in the z-direction of approximately 50 angstroms to approximately 80 angstroms. However, other values for the ranges are within the scope of the present disclosure.

Referring to FIG. 5B, in some implementations, the repeating alternate atomic layers (e.g., zirconium oxide layers 502 and aluminum oxide layers 504) shown in FIG. 5A are not visible in the final structure of the semiconductor device 200. As shown in FIG. 5B, due to subsequent thermal processing, the zirconium oxide layers 502 and aluminum oxide layers 504 blend together to form an insulator layer 240 that includes an amorphous composition of zirconium, aluminum, and oxygen (ZrAlO) where there may be molecules with Zr—O bonds, Al—O bonds, Zr—O—Al bonds, and/or Zr—Al bonds in an amorphous thin film. The insulator layer 240 may be an amorphous thin film including a non-crystalline composition containing zirconium oxide and aluminum oxide.

The amorphous structure of the insulator layer 240 has more stability as compared with other approaches that use the ZrO₂/Al₂O₃/ZrO₂ (ZAZ) dielectric layer stack as the insulator layer. In particular, the amorphous structure of the insulator layer 240 is able to better withstand crystallization at higher temperatures than if a ZAZ stack were included, which enables the insulator layer 240 to achieve lower oxygen migration. However, in some cases, the amorphous structure of the insulator layer 240 may contain a plurality of phases such as a tetragonal phase and/or a cubic phase that are more stable than the other phases.

As indicated above, FIGS. 5A and 5B are provided as examples. Other examples may differ from what is described with regard to FIGS. 5A and 5B.

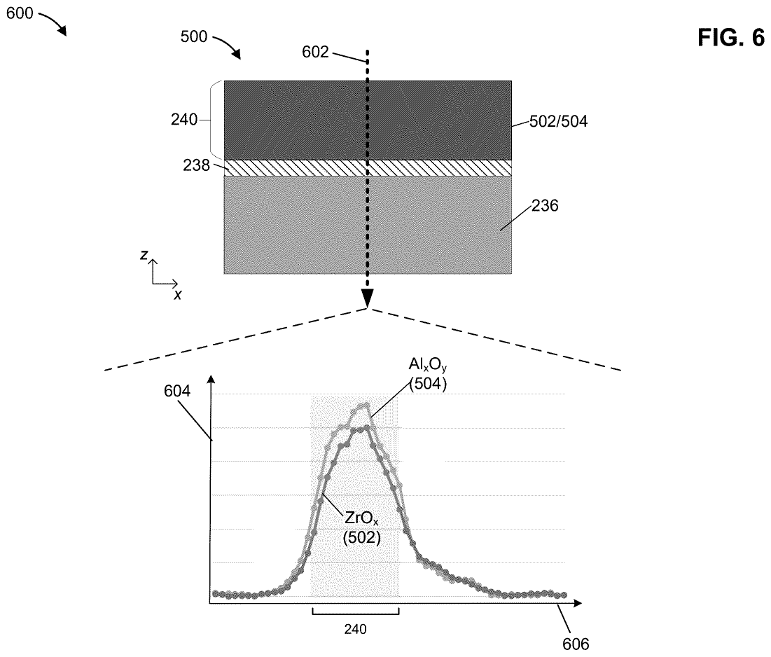

FIG. 6 illustrates an elemental composition 600 of the insulator layer 240 along a depth profile 602 of the insulator layer 240 from the example implementation 500. The elemental composition is illustrated as an atomic percentage 604 of one or more elements in the insulator layer 240 as a function of depth 606 in the insulator layer 240. In particular, the atomic percentage 604 of the one or more elements is illustrated from a top surface of the insulator layer 240 to a bottom surface of the insulator layer 240.

As shown in the depth profile 602 in FIG. 6, the insulator layer 240 may include aluminum oxide (AlₓO_{y}) and zirconium oxide (ZrOₓ). The atomic percentage 604 (or concentration) of aluminum (e.g., aluminum oxide (AlₓO_{y})) and the atomic percentage 604 (or concentration) of zirconium (e.g., zirconium oxide (ZrOₓ)) increases, peaks, and then decreases along a depth 606 of the insulator layer 240 so that the concentrations of aluminum and zirconium at or near a middle portion of the insulator layer 240 along a z-direction are greater than at or near top and bottom surfaces of the insulator layer 240.

Since the curves for aluminum oxide and zirconium oxide have approximately the same parabolic shape and have segments that are approximately parallel to each other along the depth 606 through the insulator layer 240, in some implementations, the ratio of the atomic percentage 604 (or concentration) of aluminum (e.g., aluminum oxide (AlₓO_{y})) to the atomic percentage 604 (or concentration) of zirconium (e.g., zirconium oxide (ZrOₓ)) is substantially uniform (e.g., is unchanged) along the depth 606 through the insulator layer 240.

As can be seen by the higher peak and higher points along the curve for aluminum oxide than the lower peak and lower points along the curve for zirconium oxide, in some implementations, the insulator layer 240 may include a greater atomic percentage 604 (or concentration) of aluminum (e.g., aluminum oxide (AlₓO_{y})) relative to the atomic percentage 604 (or concentration) of zirconium (e.g., zirconium oxide (ZrOₓ)) along the depth 606 through the insulator layer 240.

In some implementations, a ratio of the atomic percentage 604 (or concentration) of zirconium oxide in the insulator layer 240 to the atomic percentage 604 (or concentration) of aluminum oxide in the insulator layer 240 may be included in a range of approximately 3:4 to approximately 9:2. As noted herein, an insulator layer 240 that is a single amorphous layer avoids the interfaces between zirconium oxide and aluminum oxide and crystal defects in zirconium oxide in which traps are can be easily formed. The resulting image sensor device exhibits reduced lag. For example, in some implementations, when a single amorphous insulator layer is used, lag can be reduced by greater than 20% as compared with other approaches that use the ZrO₂/Al₂O₃/ZrO₂ (ZAZ) dielectric layer stack as an insulator layer. In the case of the ratio of the atomic percentage 604 (or concentration) of zirconium oxide in the insulator layer 240 to the atomic percentage 604 (or concentration) of aluminum oxide in the insulator layer 240 being approximately 3:4, lag is reduced by approximately 5% as compared with the other approaches. In the case of the ratio of the atomic percentage 604 (or concentration) of zirconium oxide in the insulator layer 240 to the atomic percentage 604 (or concentration) of aluminum oxide in the insulator layer 240 being approximately 3:2, lag is reduced by approximately 10% as compared with the other approaches. In the case of the ratio of the atomic percentage 604 (or concentration) of zirconium oxide in the insulator layer 240 to the atomic percentage 604 (or concentration) of aluminum oxide in the insulator layer 240 being approximately 3:1, lag is reduced by approximately 21% as compared with the other approaches. In the case of the ratio of the atomic percentage 604 (or concentration) of zirconium oxide in the insulator layer 240 to the atomic percentage 604 (or concentration) of aluminum oxide in the insulator layer 240 being approximately 9:2, lag is reduced by approximately 23% as compared with the other approaches.

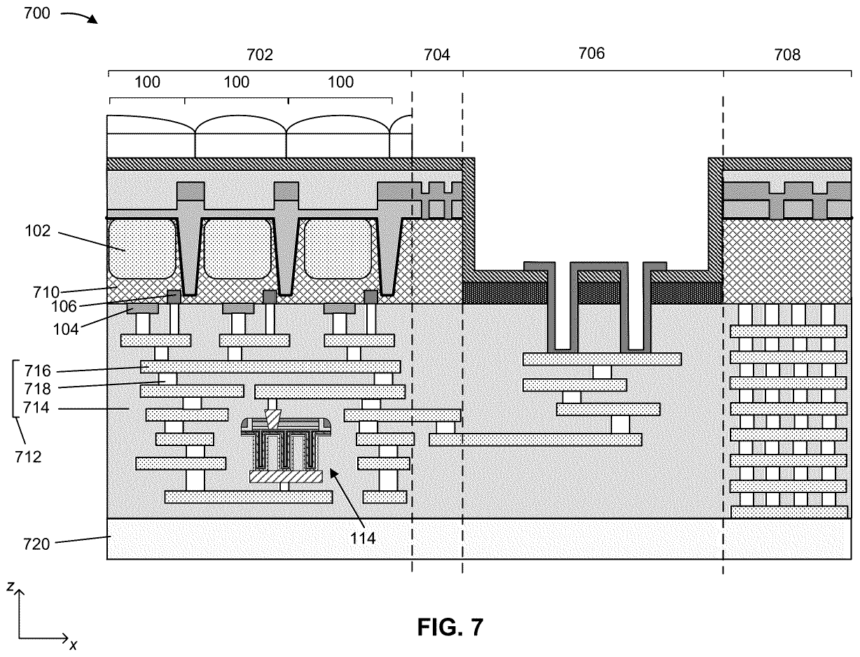

FIG. 7 is a diagram of an example semiconductor device 700 described herein. The semiconductor device 700 may include an example of a three-dimensional image sensor (e.g., a 3D CMOS image sensor). The semiconductor device 700 may be configured to be deployed in various implementations, such as digital cameras, video recorders, night-vision cameras, automotive sensors and cameras, and/or other types of light-sensing implementations.

As shown in FIG. 7, the semiconductor device 700 may include a pixel sensor array 702. The semiconductor device 700 may further include a black level correction (BLC) region 704, a bonding pad region 706, and/or a seal ring region 708, among other examples. The pixel sensor array 702 may include a plurality of pixel sensors 100 arranged in an array. The pixel sensors 100 may be configured to sense incident light and convert photons of the incident light to a photocurrent. The pixel sensors 100 may be included in a device layer 710 of the semiconductor device 700. The pixel sensors 100 may each include one or more photodiodes 102 that are configured to generate a photocurrent based on photons of incident light. The pixel sensors 100 may further include a floating diffusion node 106 in the device layer 710 that is configured to temporarily store the photocurrent generated by an associated pixel sensor 100, and may each include a transfer gate 104 that is configured to control the flow of photocurrent from a photodiode 102 to a floating diffusion node 106. The pixel sensors 100 may be formed by one or more semiconductor processing tools using various semiconductor processing techniques, such as photolithography, etching, deposition, CMP, and/or ion implantation, among other examples.

The BLC region 704 includes a metal shielding layer over a portion of the device layer 710 so that a baseline measurement of current in the device layer 710 in the BLC region 704 can be performed to determine the dark current (e.g., the current in the device layer 710 that is generated from sources other than incident light, such as heat) of the pixel sensor array 702 so that the black level of the pixel sensor array 702 can be adjusted to compensate for the dark current. The bonding pad region 706 may include one or more conductive bonding pads (or e-pads) and/or metallization layers through which electrical connections between the semiconductor device 700 and outside devices and/or external packaging may be established. The seal ring region 708 may include an arrangement of metallization structures and interconnect structures to provide structural rigidity for the semiconductor device 700 and to protect the semiconductor device 700 from ingress of humidity and other contaminants.

As further shown in FIG. 7, the semiconductor device 700 may include an interconnect layer 712 under the device layer 710. The interconnect layer 712 may include a dielectric region 714 that includes one or more dielectric layers (e.g., ILD layers, intermetal dielectric (IMD) layers, ESLs) and an arrangement of metallization structures 716 and interconnect structures 718 in the dielectric region 714. A passivation layer 720 may be included under the interconnect layer 712.

As further shown in FIG. 7, one or more overflow capacitors 114 may be included in the interconnect layer 712. The overflow capacitor(s) 114 may be structurally implemented as the trench capacitor structure 226 illustrated and described herein. An overflow capacitor 114 may be electrically coupled to a floating diffusion node 106 of a pixel sensor 100 and may be configured to store overflow photocurrent from the floating diffusion node 106.

As indicated above, FIG. 7 is provided as an example. Other examples may differ from what is described with regard to FIG. 7.

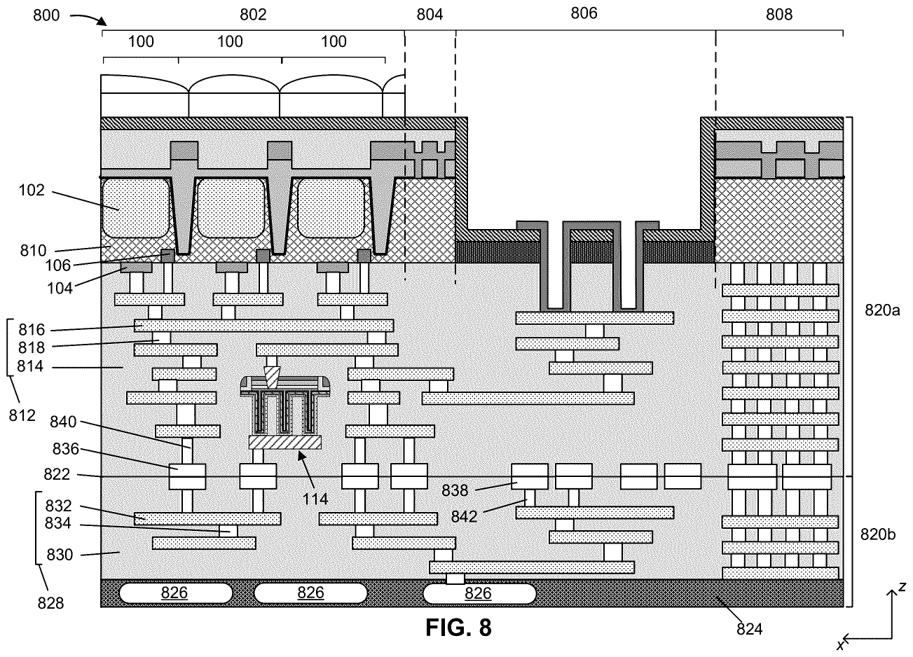

FIG. 8 is a diagram of an example semiconductor device 800 described herein. The semiconductor device 800 may include an example of a three-dimensional image sensor (e.g., a 3D CMOS image sensor). The semiconductor device 800 may be configured to be deployed in various implementations, such as digital cameras, video recorders, night-vision cameras, automotive sensors and cameras, and/or other types of light-sensing implementations.

As shown in FIG. 8, the semiconductor device 800 includes a similar combination of structures and/or layers as the semiconductor device 700. For example, the semiconductor device 800 may include elements 802-818, which are similar to the elements 702-718 of the semiconductor device 700.

However, the semiconductor device 800 includes a plurality of semiconductor dies, including a first semiconductor die 820a and a second semiconductor die 820b. The first semiconductor die 820a and the second semiconductor die 820b may be directly bonded together at a bonding interface 822 such that the first semiconductor die 820a and the second semiconductor die 820b are stacked and vertically arranged in a z-direction in the semiconductor device 800. The first semiconductor die 820a may be referred to as an image sensor die and may include the pixel sensor array 802 (including the pixel sensors 100), the BLC region 804, and the bonding pad region 806. The first semiconductor die 820a may also include the photodiodes 102, the transfer gates 104, the floating diffusion nodes 106, the device layer 810, and the interconnect layer 812 (including the dielectric region 814, the metallization structures 816 and the interconnect structures 818). In the example in FIG. 8, the overflow capacitor(s) 114 are included in the interconnect layer 812 of the first semiconductor die 820a. The seal ring region 808 may extend through both the first semiconductor die 820a and the second semiconductor die 820b.

As further shown in FIG. 8, the second semiconductor die 820b of the semiconductor device 800 may include a device layer 824, one or more integrated circuit devices 826 included in the device layer 824, and an interconnect layer 828 above the device layer 824. The interconnect layer 828 may include a dielectric region 830 that includes one or more dielectric layers (e.g., ILD layers, ESLs) and an arrangement of metallization structures 832 and interconnect structures 834 in the dielectric region 830 of the interconnect layer 828 of the second semiconductor die 820b.

The first semiconductor die 820a and the second semiconductor die 820b may be bonded at the bonding interface 822 by dielectric-to-dielectric bonds between the dielectric region 814 of the first semiconductor die 820a and the dielectric region 830 of the second semiconductor die 820b. Moreover, the first semiconductor die 820a and the second semiconductor die 820b may be bonded at the bonding interface 822 by metal-to-metal bonds between bonding pads 836 included in the interconnect layer 812 of the first semiconductor die 820a and bonding pads 838 included in the interconnect layer 828 of the second semiconductor die 820b. The bonding pads 836 may be electrically connected to the metallization structures 816 and the interconnect structures 818 in the interconnect layer 812 by bonding vias 840, and the bonding pads 838 may be electrically connected to the metallization structures 832 and the interconnect structures 834 in the interconnect layer 828 by bonding vias 842.

As indicated above, FIG. 8 is provided as an example. Other examples may differ from what is described with regard to FIG. 8.

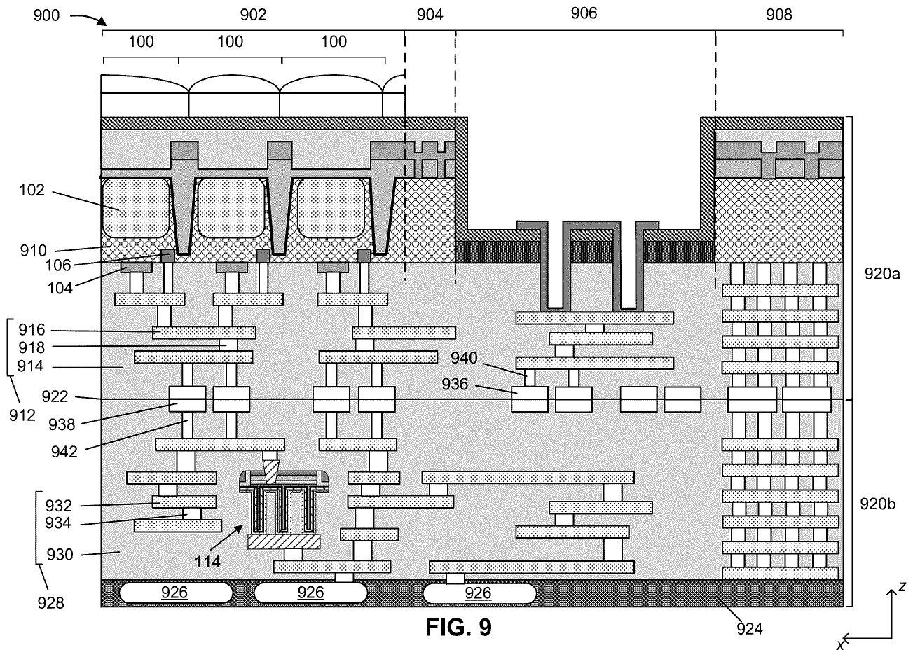

FIG. 9 is a diagram of an example semiconductor device 900 described herein. The semiconductor device 900 may include an example of a three-dimensional image sensor (e.g., a 3D CMOS image sensor). The semiconductor device 900 may be configured to be deployed in various implementations, such as digital cameras, video recorders, night-vision cameras, automotive sensors and cameras, and/or other types of light-sensing implementations.

As shown in FIG. 9, the semiconductor device 900 includes a similar combination of structures and/or layers as the semiconductor device 800. For example, the semiconductor device 900 may include elements 902-942, which are similar to the elements 802-842 of the semiconductor device 800. The semiconductor device 900 may also include pixel sensors 100, photodiodes 102, transfer gates 104, floating diffusion nodes 106, and one or more overflow capacitors 114.

However, in the semiconductor device 900, the one or more overflow capacitors 114 are included in the second semiconductor die 920b (e.g., an application-specific integrated circuit (ASIC) die) as opposed to (or in addition to) being included in the first semiconductor die 920a (e.g., the sensor die). Including the one or more overflow capacitors 114 on the second semiconductor die 920b as opposed to the first semiconductor die 920a enables a greater amount of the area in the first semiconductor die 920a to be used for the photodiodes 102 (which provides increased full well capacity for the photodiodes 102) and/or for control circuitry of the pixel sensors 100 (e.g., for the transfer gates 104, the reset gates 108, the overflow gates 112), which may increase the performance of the semiconductor device 900.

As indicated above, FIG. 9 is provided as an example. Other examples may differ from what is described with regard to FIG. 9.

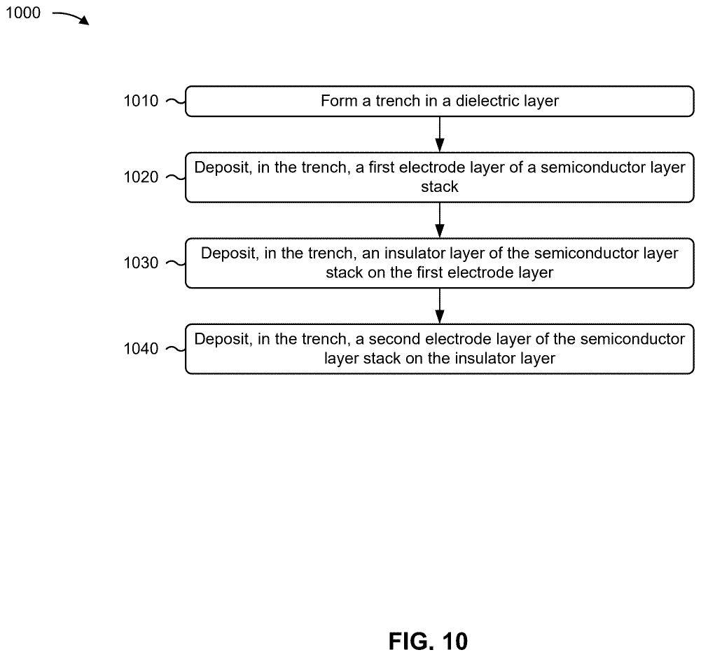

FIG. 10 is a flowchart of an example process 1000 associated with forming a semiconductor device. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming a trench in a dielectric layer (block 1010). For example, one or more semiconductor processing tools may be used to form a trench (e.g., trench 232) in a dielectric layer (e.g., ILD layer 214 and/or ESL 216), as described herein.

As further shown in FIG. 10, process 1000 may include depositing, in the trench, a first electrode layer of a semiconductor layer stack (block 1020). For example, one or more semiconductor processing tools may be used to deposit, in the trench, a first electrode layer (e.g., bottom electrode layer 236) of a semiconductor layer stack of a capacitor structure (e.g., trench capacitor structure 226), as described herein.

As further shown in FIG. 10, process 1000 may include depositing, in the trench, an insulator layer of the semiconductor layer stack on the first electrode layer (block 1030). For example, one or more semiconductor processing tools may be used to deposit, in the trench, an insulator layer (e.g., insulator layer 240) of the semiconductor layer stack on the first electrode layer, as described herein.

As further shown in FIG. 10, process 1000 may include depositing, in the trench, a second electrode layer of the semiconductor layer stack on the insulator layer (block 1040). For example, one or more semiconductor processing tools may be used to deposit, in the trench, a second electrode layer (e.g., top electrode layer 242) of the semiconductor layer stack on the insulator layer, as described herein. In some implementations, the semiconductor layer stack extends along sidewalls and a bottom surface of the trench. In some implementations, the insulator layer is an amorphous layer including a combination metals and oxygen.

Process 1000 may include additional implementations, such as any single implementation or any combination of implementations described below and/or in connection with one or more other processes described elsewhere herein.

In a first implementation, depositing the insulator layer includes performing a plurality of ALD cycles to deposit the insulator layer, where performing an ALD cycle, of the plurality of ALD cycles, includes depositing, using a first material precursor, zirconium oxide (e.g., zirconium oxide layer 502), and depositing, using a second material precursor, aluminum oxide (e.g., aluminum oxide layer 504) on the zirconium oxide.

In a second implementation, alone or in combination with the first implementation, performing the ALD cycle further includes oxidizing the first material precursor to form the zirconium oxide, and oxidizing the second material precursor to form the aluminum oxide.

In a third implementation, alone or in combination with one or more of the first and second implementations, a deposited thickness of the zirconium oxide is greater than a deposited thickness of the aluminum oxide.

In a fourth implementation, alone or in combination with one or more of the first through third implementations, a deposited thickness of the zirconium oxide is smaller than a deposited thickness of the aluminum oxide.

In a fifth implementation, alone or in combination with one or more of the first through fourth implementations, a deposited thickness of the zirconium oxide is approximately equal to a deposited thickness of the aluminum oxide.

In a sixth implementation, alone or in combination with one or more of the first through fifth implementations, the plurality of ALD cycles are performed to deposit alternating atomic layers of zirconium oxide and aluminum oxide.

In a seventh implementation, alone or in combination with one or more of the first through sixth implementations, process 1000 includes performing a surface treatment operation on the first electrode layer to transform a portion of the first electrode layer into a buffer layer (e.g., buffer layer 238) on the first electrode layer, where the surface treatment operation is performed prior to depositing the insulator layer, and the insulator layer is deposited on the buffer layer.

In an eighth implementation, alone or in combination with one or more of the first through seventh implementations, the insulator layer contains at least one of a tetragonal phase or a cubic phase.

In a ninth implementation, alone or in combination with one or more of the first through eighth implementations, the metals include aluminum and zirconium, where a ratio of a concentration of zirconium to a concentration of aluminum in the insulator layer is substantially uniform at different depths of the insulator layer.

In a tenth implementation, alone or in combination with one or more of the first through ninth implementations, the metals include aluminum and zirconium, where a concentration of zirconium in the insulator layer is greater than a concentration of aluminum in the insulator layer.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

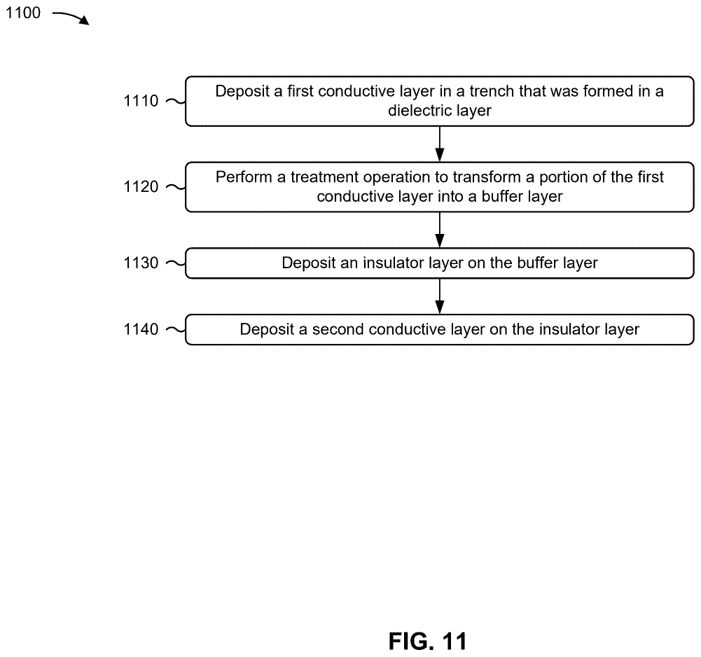

FIG. 11 is a flowchart of an example process 1100 associated with forming a semiconductor device. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include depositing a first conductive layer in a trench that was formed in a dielectric layer (block 1110). For example, one or more semiconductor processing tools may be used to deposit a first conductive layer (e.g., bottom electrode layer 236) in a trench (e.g., trench 232) that was formed in a dielectric layer (e.g., ILD layer 214 and/or ESL 216), as described herein. In some implementations, the first conductive layer extends along sidewalls and a bottom surface of the trench.

As further shown in FIG. 11, process 1100 may include performing a treatment operation to transform a portion of the first conductive layer into a buffer layer (block 1120). For example, one or more semiconductor processing tools may be used to perform a treatment operation to transform a portion of the first conductive layer into a buffer layer (e.g., buffer layer 238), as described herein.

As further shown in FIG. 11, process 1100 may include depositing an insulator layer on the buffer layer (block 1130). For example, one or more semiconductor processing tools may be used to deposit an insulator layer (e.g., insulator layer 240) on the buffer layer, as described herein. In some implementations, the insulator layer is an amorphous composition that includes a mixture of a first metal material, a second metal material, and oxygen.

As further shown in FIG. 11, process 1100 may include depositing a second conductive layer on the insulator layer (block 1140). For example, one or more semiconductor processing tools may be used to deposit a second conductive layer (e.g., top electrode layer 242) on the insulator layer, as described herein.

Process 1100 may include additional implementations, such as any single implementation or any combination of implementations described below and/or in connection with one or more other processes described elsewhere herein.

In a first implementation, at least some of the first metal material and a first portion of the oxygen are bonded to each other in a first high-k metal oxide, and at least some of the second metal material and a second portion of the oxygen are bonded to each other in a second high-k metal oxide.

In a second implementation, alone or in combination with the first implementation, depositing the insulator layer includes performing a plurality of ALD cycles to deposit alternating layers of the first high-k metal oxide and the second high-k metal oxide.

In a third implementation, alone or in combination with one or more of the first and second implementations, atomic layers of the first high-k metal oxide are deposited at a greater rate than atomic layers of the second high-k metal oxide.

In a fourth implementation, alone or in combination with one or more of the first through third implementations, the insulator layer is deposited such that a ratio of the first high-k metal oxide to the second high-k metal oxide is included in a range of approximately 3:4 to approximately 9:2.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, an image sensor device (e.g., a CMOS image sensor device) includes a capacitor structure (e.g., an MIM capacitor) that includes an insulator layer having an amorphous composition that includes a mixture of zirconium, aluminum, and oxygen. The amorphous composition reduces or prevents interface defects and electron traps as compared to crystalline insulator layer stacks such as a ZrO₂/Al₂O₃/ZrO₂ (ZAZ) dielectric layer stack. In particular, the amorphous composition of the insulator layer avoids interfaces between distinct zirconium oxide layers and an aluminum oxide layer, which reduces and/or prevents crystal defects such as oxygen vacancies from forming in the insulator layer. The resulting image sensor device exhibits reduced lag in generating images and/or video because charge trapping is reduced, minimized, and/or prevented in the capacitor structure due to the reduced and/or prevented crystal defects. For example, in some implementations, the image sensor device may exhibit a reduction in lag in generating images and/or video by greater than 20% as compared to other capacitor structures that include a ZrO₂/Al₂O₃/ZrO₂ (ZAZ) dielectric layer stack. In addition, the amorphous composition of the insulator layer may increase capacitance of the capacitor structure as compared to other capacitor structures that include a ZrO₂/Al₂O₃/ZrO₂ (ZAZ) dielectric layer stack. For example, in some implementations, capacitance of the capacitor structure can be increased by approximately 30% as compared to the other approaches.

As described in greater detail above, some implementations described herein provide a method. The method includes forming a trench in a dielectric layer. The method includes depositing, in the trench, a first electrode layer of a semiconductor layer stack. The method includes depositing, in the trench, an insulator layer of the semiconductor layer stack on the first electrode layer. The method includes depositing, in the trench, a second electrode layer of the semiconductor layer stack on the insulator layer, where the semiconductor layer stack extends along sidewalls and a bottom surface of the trench, and where the insulator layer is an amorphous layer including a combination of metals and oxygen.

As described in greater detail above, some implementations described herein provide a method. The method includes depositing a first conductive layer in a trench that was formed in a dielectric layer, where the first conductive layer extends along sidewalls and a bottom surface of the trench. The method includes performing a treatment operation to transform a portion of the first conductive layer into a buffer layer. The method includes depositing an insulator layer on the buffer layer, where the insulator layer is an amorphous composition that includes a mixture of a first metal material, a second metal material, and oxygen. The method includes depositing a second conductive layer on the insulator layer.

As described in greater detail above, some implementations described herein provide a capacitor structure. The capacitor structure includes a first electrode layer that extends along sidewalls and a bottom surface of a trench. The capacitor structure includes a second electrode layer in the trench. The capacitor structure includes an insulator layer between the first electrode layer and the second electrode layer, where the insulator layer extends along the sidewalls and the bottom surface of the trench, where the insulator layer has a non-crystalline structure that contains a mixture of a plurality of high dielectric constant (high-k) dielectric oxide materials.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a trench in a dielectric layer;
depositing, in the trench, a first electrode layer of a semiconductor layer stack;
depositing, in the trench, an insulator layer of the semiconductor layer stack on the first electrode layer; and
depositing, in the trench, a second electrode layer of the semiconductor layer stack on the insulator layer,
wherein the semiconductor layer stack extends along sidewalls and a bottom surface of the trench, and
wherein the insulator layer is an amorphous layer comprising a combination of metals and oxygen.

2. The method of claim 1, wherein depositing the insulator layer comprises:
performing a plurality of atomic layer deposition (ALD) cycles to deposit the insulator layer,
wherein performing an ALD cycle, of the plurality of ALD cycles, comprises:
depositing, using a first material precursor, zirconium oxide; and
depositing, using a second material precursor, aluminum oxide on the zirconium oxide.

3. The method of claim 2, wherein performing the ALD cycle further comprises:
oxidizing the first material precursor to form the zirconium oxide; and
oxidizing the second material precursor to form the aluminum oxide.

4. The method of claim 2, wherein a deposited thickness of the zirconium oxide is greater than a deposited thickness of the aluminum oxide.

5. The method of claim 2, wherein a deposited thickness of the zirconium oxide is smaller than a deposited thickness of the aluminum oxide.

6. The method of claim 2, wherein a deposited thickness of the zirconium oxide is approximately equal to a deposited thickness of the aluminum oxide.

7. The method of claim 2, wherein the plurality of ALD cycles are performed to deposit alternating atomic layers of zirconium oxide and aluminum oxide.

8. The method of claim 1, further comprising performing a surface treatment operation on the first electrode layer to transform a portion of the first electrode layer into a buffer layer on the first electrode layer,
wherein the surface treatment operation is performed prior to depositing the insulator layer and the insulator layer is deposited on the buffer layer.

9. The method of claim 1, wherein the insulator layer contains at least one of a tetragonal phase or a cubic phase.

10. The method of claim 1, wherein the metals comprise aluminum and zirconium, and
wherein a ratio of a concentration of zirconium to a concentration of aluminum in the insulator layer is substantially uniform at different depths of the insulator layer.

11. The method of claim 1, wherein the metals comprise aluminum and zirconium, and
wherein a concentration of zirconium in the insulator layer is greater than a concentration of aluminum in the insulator layer.

12. A method, comprising:
depositing a first conductive layer in a trench that was formed in a dielectric layer,
wherein the first conductive layer extends along sidewalls and a bottom surface of the trench;
performing a treatment operation to transform a portion of the first conductive layer into a buffer layer;
depositing an insulator layer on the buffer layer,
wherein the insulator layer is an amorphous composition that includes a mixture of a first metal material, a second metal material, and oxygen; and
depositing a second conductive layer on the insulator layer.

13. The method of claim 12, wherein at least some of the first metal material and a first portion of the oxygen are bonded to each other in a first high dielectric constant (high-k) metal oxide, and at least some of the second metal material and a second portion of the oxygen are bonded to each other in a second high-k metal oxide.

14. The method of claim 13, wherein depositing the insulator layer comprises:
performing a plurality of atomic layer deposition (ALD) cycles to deposit alternating layers of the first high-k metal oxide and the second high-k metal oxide.

15. The method of claim 14, wherein atomic layers of the first high-k metal oxide are deposited at a greater rate than atomic layers of the second high-k metal oxide.

16. The method of claim 14, wherein the insulator layer is deposited such that a ratio of the first high-k metal oxide to the second high-k metal oxide is included in a range of approximately 3:4 to approximately 9:2.

17. A capacitor structure, comprising:
a first electrode layer that extends along sidewalls and a bottom surface of a trench;
a second electrode layer in the trench; and
an insulator layer between the first electrode layer and the second electrode layer,
wherein the insulator layer extends along the sidewalls and the bottom surface of the trench, and
wherein the insulator layer has a non-crystalline structure that contains a mixture of a plurality of high dielectric constant (high-k) dielectric oxide materials.

18. The capacitor structure of claim 17, wherein a first high-k dielectric oxide material of the plurality of high-k dielectric oxide materials comprises zirconium oxide, and a second high-k dielectric oxide material of the plurality of high-k dielectric oxide materials comprises aluminum oxide.

19. The capacitor structure of claim 17, wherein the plurality of high-k dielectric oxide materials have different concentrations from each other in the insulator layer.

20. The capacitor structure of claim 17, wherein the insulator layer is a single amorphous layer.
